(19) United States
(12) Patent Application Publication
(10) Pub. No.: US 2025/0248102 A1
(43) Pub. Date: Jul. 31, 2025

(54) SEMICONDUCTOR DEVICE AND METHOD OF FABRICATING THE SAME

(71) Applicant: Samsung Electronics Co., Ltd., Suwon-si (KR)

(72) Inventors: Young Dae CHO, Suwon-si (KR); Hyo Jin KIM, Suwon-si (KR); Yong Jun NAM, Suwon-si (KR); Tae Hyung LEE, Suwon-si (KR); Sung Keun LIM, Suwon-si (KR); In Geon HWANG, Suwon-si (KR)

(73) Assignee: Samsung Electronics Co., Ltd., Suwon-si (KR)

(21) Appl. No.: 18/775,310

(22) Filed: Jul. 17, 2024

(30) Foreign Application Priority Data
Jan. 29, 2024 (KR) 10-2024-0013445

(51) Int. Cl. H01L 29/417; H01L 21/306; H01L 29/06; H01L 29/423; H01L 29/66; H01L 29/775

(52) U.S. Cl. CPC H10D 64/258; H01L 21/306; H10D 30/014; H10D 30/43; H10D 30/6735; H10D 62/121; H10D 64/017; H10D 64/021

(57) ABSTRACT

A method of fabricating a semiconductor device is provided. The method of fabricating the semiconductor device includes etching a stack structure to form a first trench on a first side of a dummy gate on a stack structure a second trench on a second side of the dummy gate opposite to the first side of the dummy gate, wherein the second semiconductor layer that remain after the formation of the first and second trenches form a plurality of nanosheets, partially etching the first and second trenches to form a third trench a fourth trench, forming a first sacrificial pattern inside the fourth trench, and forming a first source/drain region inside the third trench and a second source/drain region on the top surface of the first sacrificial pattern inside the fourth trench.

### CROSS-REFERENCE TO RELATED APPLICATION

This application claims priority from Korean Patent Application No. 10-2024-0013445 filed on Jan. 29, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device and a method of fabricating the same, and more particularly, to a semiconductor device including a multi-bridge channel field-effect transistor (MBCFET™) and a method of fabricating the semiconductor device.

### 2. Description of the Related Art

As a scaling technique for increasing the density of integrated circuit devices, the concept of a multi-gate transistor has been proposed in which a silicon body in the form of a fin or nanowire is formed on a substrate and a gate is formed on the surface of the silicon body.

The multi-gate transistor takes advantage of its three-dimensional (3D) channel, allowing for easy scaling both up and down. Additionally, the multi-gate transistor offers improved control over the current without the need to increase the gate length. Furthermore, the multi-gate transistor effectively mitigates the short channel effect (SCE), which is the phenomenon where the electric potential of a channel region is affected by the drain voltage.

### SUMMARY

Aspects of the present disclosure provide a method of fabricating a semiconductor device with improved reliability and the semiconductor device itself, in which parts of the sidewalls of semiconductor layers formed between a plurality of nanosheets are etched before the formation of a sacrificial pattern that is to be replaced by a bottom source/drain contact, in a structure where a bottom source/drain contact is disposed in a source/drain region. As a result, during the formation of the sacrificial pattern, the epitaxial growth of the semiconductor layers may be suppressed, thereby preventing adjacent semiconductor layers from merging.

However, aspects of the present disclosure are not restricted to those set forth herein. The above and other aspects of the present disclosure will become more apparent to one of ordinary skills in the art to which the present disclosure pertains by referencing the detailed description of the present disclosure given below.

According to an aspect of the present disclosure, there is provided a method of fabricating a semiconductor device, comprising forming an active pattern extending in a first horizontal direction on a substrate; forming a stacked structure on the active pattern, the stacked structure including alternating first semiconductor layers and second semiconductor layers; forming a dummy gate on the stacked structure such that the dummy gate extends in a second horizontal direction different from the first horizontal direction; etching the stacked structure such that a first trench is formed on a first side of the dummy gate and a second trench extending into the substrate is formed on a second side of the dummy gate opposite to the first side of the dummy gate in the first horizontal direction, and such that a plurality of nanosheets are formed from portions of the second semiconductor layers that remain after the first and second trenches are formed; converting the first trench to a third trench and the second trench to a fourth trench by partially etching sidewalls of the first semiconductor layers exposed through the first and second trenches; forming a first sacrificial pattern inside the fourth trench, wherein a top surface of the first sacrificial pattern is formed lower than a top surface of the active pattern; forming a first source/drain region inside the third trench, and a second source/drain region on the top surface of the first sacrificial pattern inside the fourth trench; forming a contact trench exposing a bottom surface of the second source/drain region by removing at least a portion of the first sacrificial pattern; and forming a bottom source/drain contact inside the contact trench.

According to an aspect of the present disclosure, there is provided a method of fabricating a semiconductor device, comprising forming an active pattern extending in a first horizontal direction on a substrate; forming a stacked structure on the active pattern such that the stack structure includes alternating first semiconductor layers and second semiconductor layers; forming a dummy gate on the stacked structure such that the dummy gate extends in a second direction different from the first horizontal direction; etching the stacked structure such that a first trench extending into the substrate is formed on a first side of the dummy gate and a second trench extending into the substrate is formed on a second side of the dummy gate opposite to the first side of the dummy gate in the first horizontal direction and such that a plurality of nanosheets are formed from portions of the second semiconductor layers that remain after the first and second trenches are formed; converting the first trench to a third trench and the second trench to a fourth trench by partially etching sidewalls the first semiconductor layers exposed through the first trench, and by partially etching the sidewalls of the first semiconductor layers exposed through the second trench; forming a first sacrificial pattern inside the third trench, and a second sacrificial pattern in the fourth trench such that top surfaces of the first and second sacrificial patterns are lower than a top surface of the active pattern; forming a first source/drain region on the top surface of the first sacrificial pattern inside the third trench and a second source/drain region on the top surface of the second sacrificial pattern inside the fourth trench; forming an upper interlayer insulating layer such that the upper interlayer insulating layer covers each of the first and second source/drain regions; removing the dummy gate and the first semiconductor layers; forming a gate insulating layer on a surface exposed by the removing the dummy gate and the first semiconductor layers; forming a gate electrode on the gate insulating layer such that the gate electrode surrounds the plurality of nanosheets; forming an upper source/drain contact extending to the first source/drain region by penetrating the upper interlayer insulating layer in a vertical direction; forming a contact trench exposing a bottom surface of the second source/drain region by removing the second sacrificial pattern; and forming a bottom source/drain contact inside the contact trench, wherein at least part of the first source/drain region and at least part of the second source/drain region are formed between nanosheets, of the plurality of nanosheets, adjacent to each other in the vertical direction, and wherein the gate insulating layer is in contact with each of the first and second source/drain regions.

According to an aspect of the present disclosure, there is provided a semiconductor device, comprising a lower interlayer insulating layer; an insulating pattern extending in a first horizontal direction on the lower interlayer insulating layer; a plurality of nanosheets stacked on the insulating pattern spaced apart from one another in a vertical direction; a gate electrode extending in a second horizontal direction different from the first horizontal direction on the insulating pattern, the gate electrode surrounding the plurality of nanosheets; a first source/drain region on a first side of the gate electrode such that the first source/drain region contacts first sidewalls of the plurality of nanosheets; a second source/drain region on a second side of the gate electrode opposite to the first side of the gate electrode in the first horizontal direction such that the second source/drain region contacts second sidewalls of the plurality of nanosheets opposite to the first sidewalls of the plurality of nanosheets; and a bottom source/drain contact penetrating the lower interlayer insulating layer and the insulating pattern in the vertical direction such that the bottom source/drain contact is electrically connected to the second source/drain region, wherein at least part of the second source/drain region is disposed between nanosheets, of the plurality of nanosheets, adjacent to each other in the vertical direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout view of a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIGS. 4 through 24 are cross-sectional views for explaining intermediate steps of a method of fabricating a semiconductor device according to some embodiments of the present disclosure;

FIGS. 25 through 28 are cross-sectional views for explaining intermediate steps of a method of fabricating a semiconductor device according to other embodiments of the present disclosure;

FIG. 29 is a cross-sectional view for explaining a semiconductor device according to other embodiments of the present disclosure;

FIG. 30 is a cross-sectional view for explaining a semiconductor device according to other embodiments of the present disclosure;

FIG. 31 is a cross-sectional view for explaining a semiconductor device according to other embodiments of the present disclosure; and

FIGS. 32 through 36 are cross-sectional views for explaining intermediate steps of a method of fabricating a semiconductor device according to other embodiments of the present disclosure.

### DETAILED DESCRIPTION

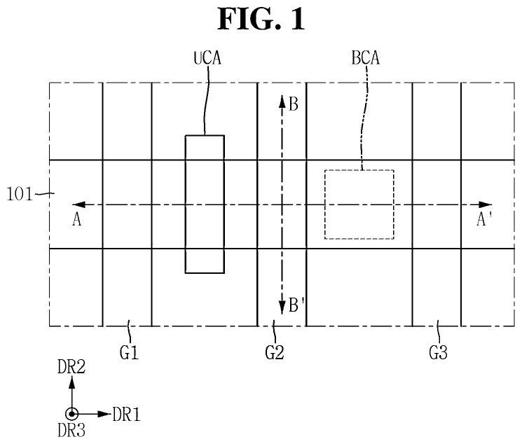

A semiconductor device according to some embodiments of the present disclosure will hereinafter be described with reference to FIGS. 1 through 3.

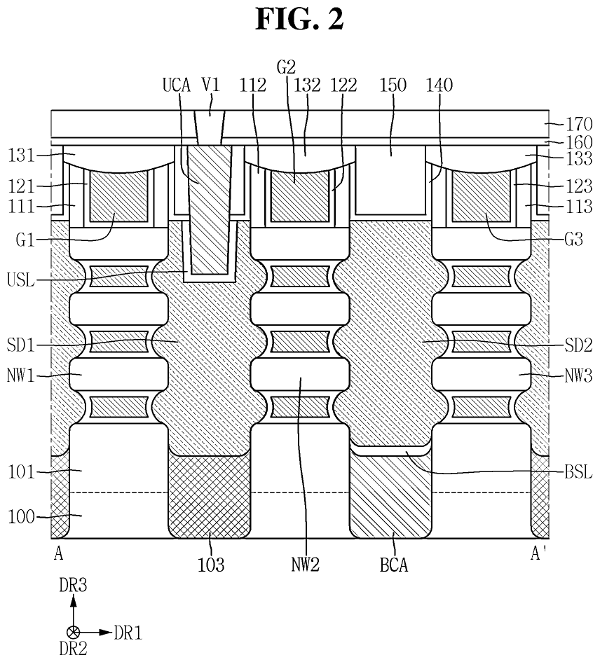

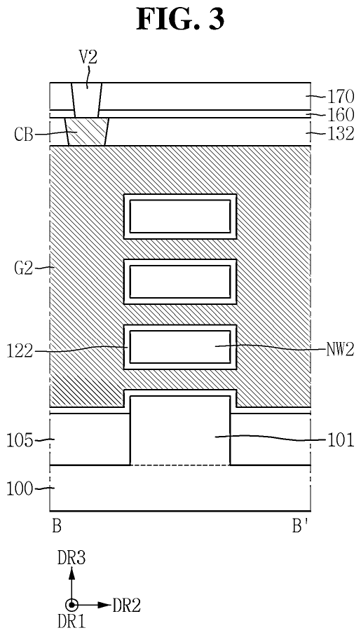

FIG. 1 is a layout view for explaining a semiconductor device according to some embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 through 3, the semiconductor device according to some embodiments of the present disclosure includes a lower interlayer insulating layer 100, an insulating pattern 101, a first sacrificial pattern 103, a field insulating layer 105, first plurality of nanosheets NW1, second plurality of nanosheets NW2, third plurality of nanosheets NW3, first, second, and third gate electrodes G1, G2, and G3, first gate spacers 111, second gate spacers 112, and third gate spacers 113, first, second, and third gate insulating layers 121, 122, and 123, first, second, and third capping patterns 131, 132, and 133, first and second source/drain regions SD1 and SD2, a first etch stop layer 140, a first upper interlayer insulating layer 150, a gate contact CB, an upper source/drain contact UCA, a bottom source/drain contact BCA, an upper silicide layer USL, a bottom silicide layer BSL, a second etch stop layer 160, a second upper interlayer insulating layer 170, and first and second vias V1 and V2.

The lower interlayer insulating layer 100 may include an electrically insulating material, for example, at least one of silicon oxide, silicon nitride, silicon oxynitride, a low-k material, etc. The low-k material may be, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxy ditertiary butoxy siloxane (DADBS), trimethylsilil phosphate (TMSP), polytetrafluoroethylene (PTFE), tonen silazen (TOSZ), fluoride silicate glass (FSG), polyimide nanofoam such as polypropylene oxide, carbon doped silicon oxide (CDO), organo silicate glass (OSG), SiLK, amorphous fluorinated carbon, silica aerogel, silica xerogel, mesoporous silica, a combination thereof, and/or the like, but the present disclosure is not limited thereto.

First and second horizontal directions DR1 and DR2 may be defined as directions parallel to the top surface of the lower interlayer insulating layer 100. The second horizontal direction DR2 may be defined as a different direction from the first horizontal direction DR1. A vertical direction DR3 is defined as a direction perpendicular to both the first and second horizontal directions DR1 and DR2. That is, the vertical direction DR3 is defined as a direction perpendicular to the top surface of the lower interlayer insulating layer 100.

The insulating pattern 101 may extend in the first horizontal direction DR1 on the top surface of the lower interlayer insulating layer 100. The insulating pattern 101 may include periodic protrusions of an insulating material protruding in the vertical direction DR3 from the top surface of the lower interlayer insulating layer 100. The insulating pattern 101 may include an insulating material. For example, the insulating pattern 101 may include the same material as the lower interlayer insulating layer 100.

The field insulating layer 105 may be disposed on the top surface of the lower interlayer insulating layer 100. The field insulating layer 105 may surround the sidewalls of the insulating pattern 101. For example, the top surface of the insulating pattern 101 may protrude in the vertical direction DR3 beyond the top surface of the field insulating layer 105, but the present disclosure is not limited thereto. In other embodiments, the top surface of the insulating pattern 101 may be formed on the same plane as the top surface of the field insulating layer 105. The field insulating layer 105 may include, for example, an oxide film, a nitride film, an oxynitride film, a combination thereof, and/or the like.

The first plurality of nanosheets NW1 may be disposed on the insulating pattern 101. The first plurality of nanosheets NW1 may be disposed at the intersection of the insulating pattern 101 and the first gate electrode G1. The second plurality of nanosheets NW2 may be disposed on the insulating pattern 101. The second plurality of nanosheets NW2 may be disposed at the intersection of the insulating pattern 101 and the second gate electrode G2. The second plurality of nanosheets NW2 may be spaced apart from the first plurality of nanosheets NW1 in the first horizontal direction DR1. The third plurality of nanosheets NW3 may be disposed on the insulating pattern 101. The third plurality of nanosheets NW3 may be disposed at the intersection of the insulating pattern 101 and the third gate electrode G3. The third plurality of nanosheets NW3 may be spaced apart from the second plurality of nanosheets NW2 in the first horizontal direction DR1.

Each of the first plurality of nanosheets NW1, the second plurality of nanosheets NW2, and the third plurality of nanosheets NW3 may include stacks of multiple nanosheets that are vertically spaced apart in the vertical direction DR3. In FIGS. 2 and 3, the first plurality of nanosheets NW1, the second plurality of nanosheets NW2, and the third plurality of nanosheets NW3 are illustrated as including three stacks of nanosheets that are stacked in the vertical direction DR3 to be spaced apart from one another, but the present disclosure is not limited thereto. For example, in other embodiments, the first plurality of nanosheets NW1, the second plurality of nanosheets NW2, and the third plurality of nanosheets NW3 may include four or more stacks of nanosheets that are stacked in the vertical direction DR3 to be spaced apart from one another. In at least one embodiment, each of the stacks of nanosheets may include a plurality of nanosheets. For example, the first plurality of nanosheets NW1, the second plurality of nanosheets NW2, and the third plurality of nanosheets NW3 may include stacks of, e.g., silicon nanosheets (SiNS), but the present disclosure is not limited thereto. Alternatively, in other embodiments, the first plurality of nanosheets NW1, the second plurality of nanosheets NW2, and the third plurality of nanosheets NW3 may include silicon germanium (SiGe).

The first gate electrode G1 may extend in the second horizontal direction DR2 over the insulating pattern 101 and the field insulating layer 105. The first gate electrode G1 may surround the first plurality of nanosheets NW1. The second gate electrode G2 may extend in the second horizontal direction DR2 over the insulating pattern 101 and the field insulating layer 105. The second gate electrode G2 may surround the second plurality of nanosheets NW2. The second gate electrode G2 may be spaced apart from the first gate electrode G1 in the first horizontal direction DR1. The third gate electrode G3 may extend in the second horizontal direction DR2 over the insulating pattern 101 and the field insulating layer 105. The third gate electrode G3 may surround the third plurality of nanosheets NW3. The third gate electrode G3 may be spaced apart from the second gate electrode G2 in the first horizontal direction DR1.

The first, second, and third gate electrodes G1, G2, and G3 may include an electrically conductive material, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof. For example, the first, second, and third gate electrodes G1, G2, and G3 may include a conductive metal oxide or conductive metal oxynitride, and may also include an oxidized form of any one of the aforementioned materials.

The first gate spacers 111 may extend in the second horizontal direction DR2 along both sidewalls of the first gate electrode G1 on the top surface of the uppermost nanosheet of the first plurality of nanosheets NW1 and on the field insulating layer 105. The second gate spacers 112 may extend in the second horizontal direction DR2 along both sidewalls of the second gate electrode G2 on the top surface of the uppermost nanosheet of the second plurality of nanosheets NW2 and on the field insulating layer 105. The third gate spacers 113 may extend in the second horizontal direction DR2 along both sidewalls of the third gate electrode G3 on the top surface of the uppermost nanosheet of the third plurality of nanosheets NW3 and on the field insulating layer 105.

The first gate spacers 111, the second gate spacers 112, and the third gate spacers 113 may include an electrically insulating material, such as at least one of silicon nitride (SiN), silicon oxide (SiO₂), silicon oxycarbonitride (SiOCN), silicon boron nitride (SiBN), silicon oxyboron nitride (SiOBN), silicon oxycarbide (SiOC), and/or a combination thereof, but the present disclosure is not limited thereto.

The first source/drain region SD1 may be disposed on a first side of the second gate electrode G2. For example, the first source/drain region SD1 may be disposed between the first and second gate electrodes G1 and G2. For example, the first source/drain region SD1 may be convexly formed toward the first gate electrode G1 between the insulating pattern 101 and the lowermost nanosheet of the first plurality of nanosheet NW1. That is, at least part of the first source/drain region SD1 may be disposed between the insulating pattern 101 and the lowermost nanosheet of the first plurality of nanosheet NW1. For example, the first source/drain region SD1 may be convexly formed toward the first gate electrode G1 between the first plurality of nanosheets NW1 that are adjacent to one another. That is, at least part of the first source/drain region SD1 may be disposed between the first plurality of nanosheets NW1 that are adjacent to one another (e.g., in the vertical direction DR3).

Furthermore, the first source/drain region SD1 may be convexly formed toward the second gate electrode G2 between the insulating pattern 101 and the lowermost nanosheet of the second plurality of nanosheet NW2. That is, at least part of the first source/drain region SD1 may be disposed between the insulating pattern 101 and the lowermost nanosheet of the second plurality of nanosheet NW2. For example, the first source/drain region SD1 may be convexly formed toward the second gate electrode G2 between the second plurality of nanosheets NW2 that are adjacent to one another. That is, at least part of the first source/drain region SD1 may be disposed between the second plurality of nanosheets NW2 that are adjacent to one another (e.g., in the vertical direction DR3).

For example, the first source/drain region SD1 may be in contact with both sidewalls, in the first horizontal direction DR1, of each of the first plurality of nanosheets NW1. Additionally, the first source/drain region SD1 may be in contact with first sidewalls of the second plurality of nanosheets NW2 that are on first sides, in the first horizontal direction DR1, of the second plurality of nanosheets NW2. For example, the bottom surface of the first source/drain region SD1 may be formed lower than an upper (e.g., the topmost surface) of the insulating pattern 101. In at least one example, the first source/drain region SD1 may include SiGe.

The second source/drain region SD2 may be disposed on a second side of the second gate electrode G2 that is opposite to the first side of the second gate electrode G2 in the first horizontal direction D1. For example, the second source/drain region SD2 may be disposed between the second and third gate electrodes G2 and G3. For example, the second source/drain region SD2 may be convexly formed toward the second gate electrode G2 between the insulating pattern 101 and the lowermost nanosheet of the second plurality of nanosheet NW2. That is, at least part of the second source/drain region SD2 may be disposed between the insulating pattern 101 and the lowermost nanosheet of the second plurality of nanosheet NW2. For example, the second source/drain region SD2 may be convexly formed toward the second gate electrode G2 between the second plurality of nanosheets NW1 that are adjacent to one another. That is, at least part of the second source/drain region SD2 may be disposed between the second plurality of nanosheets NW2 that are adjacent to one another (e.g., in the vertical direction DR3).

Furthermore, the second source/drain region SD2 may be convexly formed toward the third gate electrode G3 between the insulating pattern 101 and the lowermost nanosheet of the third plurality of nanosheet NW3. That is, at least part of the second source/drain region SD2 may be disposed between the insulating pattern 101 and the lowermost nanosheet of the third plurality of nanosheet NW3. For example, the second source/drain region SD2 may be convexly formed toward the third gate electrode G3 between the third plurality of nanosheets NW3 that are adjacent to one another. That is, at least part of the second source/drain region SD2 may be disposed between the third plurality of nanosheets NW3 that are adjacent to one another (e.g., in the vertical direction DR3).

For example, the second source/drain region SD2 may be in contact with both sidewalls, in the first horizontal direction DR1, of each of the third plurality of nanosheets NW3. Additionally, the second source/drain region SD2 may be in contact with second sidewalls of the second plurality of nanosheets NW2 that are opposite to the first sidewalls of the second plurality of nanosheets NW2. For example, the bottom surface of the second source/drain region SD2 may be formed lower than the top surface of the insulating pattern 101. In at least one example, the second source/drain region SD2 may include SiGe.

The first sacrificial pattern 103 may be disposed below the first source/drain region SD1. The first sacrificial pattern 103 may be in contact with the bottom surface of the first source/drain region SD1. The first sacrificial pattern 103 may penetrate each of the insulating pattern 101 and the lower interlayer insulating layer 100 in the vertical direction DR3. For example, the bottom surface of the first sacrificial pattern 103 may be formed on the same plane as the bottom surface of lower interlayer insulating layer 100, but the present disclosure is not limited thereto. Alternatively, in some embodiments, the lower interlayer insulating layer 100 may cover the bottom surface of the first sacrificial pattern 103. For example, both sidewalls, in the first horizontal direction DR1, of the first sacrificial pattern 103 may be in contact with each of the insulating pattern 101 and the lower interlayer insulating layer 100. The first sacrificial pattern 103 may include a different material from each of the lower interlayer insulating layer 100 and the insulating pattern 101. For example, in at least one embodiment, the first sacrificial pattern 103 may include SiGe.

The first gate insulating layer 121 may be disposed between the first gate electrode G1 and the insulating pattern 101. The first gate insulating layer 121 may also be disposed between the first gate electrode G1 and the field insulating layer 105. The first gate insulating layer 121 may also be disposed between the first gate electrode G1 and the first gate spacers 111. The first gate insulating layer 121 may also be disposed between the first gate electrode G1 and the first plurality of nanosheets NW1. The first gate insulating layer 121 may also be disposed between the first gate electrode G1 and the first source/drain region SD1.

The second gate insulating layer 122 may be disposed between the second gate electrode G2 and the insulating pattern 101. The second gate insulating layer 122 may also be disposed between the second gate electrode G2 and the field insulating layer 105. The second gate insulating layer 122 may also be disposed between the second gate electrode G2 and the second gate spacers 112. The second gate insulating layer 122 may also be disposed between the second gate electrode G2 and the second plurality of nanosheets NW2. The second gate insulating layer 122 may also be disposed between the second gate electrode G2 and the first source/drain region SD1. The second gate insulating layer 122 may also be disposed between the second gate electrode G2 and the second source/drain region SD2.

The third gate insulating layer 123 may be disposed between the third gate electrode G3 and the insulating pattern 101. The third gate insulating layer 123 may also be disposed between the third gate electrode G3 and the field insulating layer 105. The third gate insulating layer 123 may also be disposed between the third gate electrode G3 and the third gate spacers 113. The third gate insulating layer 123 may also be disposed between the third gate electrode G3 and the third plurality of nanosheets NW3. The third gate insulating layer 123 may also be disposed between the third gate electrode G3 and the second source/drain region SD1.

Each of the first, second, and third gate insulating layers 121, 122, and 123 may be in contact with the insulating pattern 101. In at least one example, the first and second gate insulating layers 121 and 122 may be in contact with the first source/drain region SD1. Additionally, the second and third gate insulating layers 122 and 123 may be in contact with the second source/drain region SD2. However, the present disclosure is not limited to this. In some embodiments, inner spacers (not illustrated) may be disposed between the first source/drain region SD1 and the first and/or second gate insulating layers 121 and 122 and/or between the second source/drain region SD2 and the second and/or third gate insulating layers 122 and 123. The inner spacers may include an electrically insulating material, for example, at least one of SiN, SiON, SiO₂, SiOCN, SiBN, SiOBN, SiOC, and/or a combination thereof.

The first, second, and third gate insulating layers 121, 122, and 123 may include an electrically insulating material, such as at least one of silicon oxide, silicon oxynitride, silicon nitride, and a high-k material with a greater dielectric constant than silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or the like.

The semiconductor device according to some embodiments of the present disclosure may include negative capacitance (NC) FETs using negative capacitors. For example, each of the first, second, and third gate insulating layers 121, 122, and 123 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film may have a sub-threshold swing (SS) of less than 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, =lead zirconium titanium oxide, a combination thereof, and/or the like. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of dopant may vary depending on the type of material of the ferroelectric material film.

If the ferroelectric material film includes hafnium oxide, the dopant of the ferroelectric material film may include, for example, at least one of Gd, Si, Zr, Al, and Y.

If the dopant of the ferroelectric material film is Al, the ferroelectric material film may include about 3 atomic % (at %) to about 8 at % of Al. Here, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include about 2 at % to about 10 at % of Si. If the dopant of the ferroelectric material film is Y, the ferroelectric material film may include about 2 at % to about 10 at % of Y. If the dopant of the ferroelectric material film is Gd, the ferroelectric material film may include about 1 at % to about 7 at % of Gd. If the dopant of the ferroelectric material film is Zr, the ferroelectric material film may include about 50 at % to about 80 at % of Zr.

The paraelectric material film may include paraelectric properties. The paraelectric material film may include, for example, at least one of silicon oxide and a high-k metal oxide. The high-k metal oxide may include, for example, at least one of hafnium oxide, zirconium oxide, and aluminum oxide, but the present disclosure is not limited thereto.

The ferroelectric material film and the paraelectric material film may include the same material. For example, if the ferroelectric material film and the paraelectric material film include hafnium oxide, the hafnium oxide included in the ferroelectric material film may have a different crystalline structure from the hafnium oxide included in the paraelectric material film. Thus, both the ferroelectric material film and the paraelectric film may include the same base material, but the ferroelectric material film may have ferroelectric properties, and the paraelectric material film may not have ferroelectric properties.

The ferroelectric material film may be thick enough to exhibit ferroelectric properties. The ferroelectric material film may have a thickness of, for example, about 0.5 nm to about 10 nm, but the present disclosure is not limited thereto. A critical thickness that may exhibit ferroelectric properties may vary depending on the type of ferroelectric material, and thus, the thickness of the ferroelectric material film may vary depending on the type of ferroelectric material included in the ferroelectric material film.

For example, each of the first, second, and third gate insulating layers 121, 122, and 123 may include a ferroelectric material film. In another example, each of the first, second, and third gate insulating layers 121, 122, and 123 may include a plurality of ferroelectric material films that are spaced apart from each other. For example, each of the first, second, and third gate insulating layers 121, 122, and 123 may include a stack of a plurality of ferroelectric material films and a plurality of paraelectric material films that are alternately stacked with the ferroelectric material films.

The first etch stop layer 140 may be disposed on the sidewalls, in the first horizontal direction DR1, of each of the first gate spacers 111, second gate spacers 112, and third gate spacers 113. The first etch stop layer 140 may also be disposed on the top surfaces of the first and second source/drain regions SD1 and SD2. Although not illustrated, the first etch stop layer 140 may be disposed on the sidewalls, in the second horizontal direction DR2, of each of the first and second source/drain regions SD1 and SD2. For example, the first etch stop layer 140 may be conformally formed. The first etch stop layer 140 may include, for example, at least one of aluminum oxide, aluminum nitride, hafnium oxide, zirconium oxide, silicon oxide, silicon nitride, silicon oxynitride, and a low-k material.

The first capping pattern 131 may extend in the second horizontal direction DR2 over each of the first gate spacers 111, the first gate insulating layer 121, and the first gate electrode G1. The second capping pattern 132 may extend in the second horizontal direction DR2 over each of the second gate spacers 112, the second gate insulating layer 122, and the second gate electrode G2. The third capping pattern 133 may extend in the second horizontal direction DR2 over each of the third gate spacers 113, the third gate insulating layer 123, and the third gate electrode G3.

For example, the bottom surfaces of the first, second, and third capping patterns 131, 132, and 133 may be in contact with the first etch stop layer 140, but the present disclosure is not limited thereto. In some embodiments, the sidewalls of each of the first, second, and third capping patterns 131, 132, and 133 may also be in contact with the first etch stop layer 140. The first, second, and third capping patterns 131, 132, and 133 may include, for example, at least one of SiN, SiON, SiO₂, SiCN, SiOCN, and a combination thereof, but the present disclosure is not limited thereto.

The first upper interlayer insulating layer 150 may be disposed on the first etch stop layer 140. The first upper interlayer insulating layer 150 may be disposed on the sidewalls of each of the first, second, and third capping patterns 131, 132, and 133. The first upper interlayer insulating layer 150 may cover each of the first and second source/drain regions SD1 and SD2 on the field insulating layer 105. For example, the top surface of the first upper interlayer insulating layer 150 may be formed on the same plane as the top surfaces of the first, second, and third capping patterns 131, 132, and 133. The first upper interlayer insulating layer 150 may include an electrically insulating material, for example, at least one of silicon oxide, silicon nitride, silicon oxynitride, and/or a low-k material.

The upper source/drain contact UCA may be disposed between the first and second gate electrodes G1 and G2. The upper source/drain contact UCA may be disposed above the first source/drain region SD1. The upper source/drain contact UCA may extend into the first source/drain region SD1 by penetrating the first upper interlayer insulating layer 150 and the first etch stop layer 140 in the vertical direction DR3. The upper source/drain contact UCA may be electrically connected to the first source/drain region SD1. In FIG. 2, the upper source/drain contact UCA is illustrated as being formed as a single layer, but the present disclosure is not limited thereto. For example, in other embodiments, the upper source/drain contact UCA may be formed as a multilayer.

In at least some embodiments, the top surface of the upper source/drain contact UCA may be formed on the same plane as the top surface of the first upper interlayer insulating layer 150, but the present disclosure is not limited thereto. For example, in other embodiments, the top surface of the upper source/drain contact UCA may be formed higher than the top surface of the first upper interlayer insulating layer 150. The upper source/drain contact UCA may include a conductive material such as a metal.

The upper silicide layer USL may be disposed between the upper source/drain contact UCA and the first source/drain region SD1. The upper silicide layer USL may be disposed along the boundary between the upper source/drain contact UCA and the first source/drain region SD1. For example, the upper silicide layer USL may include a metal silicide material.

The gate contact CB may be located above the second gate electrode G2. The gate contact CB may be connected to the second gate electrode G2 by penetrating the second capping pattern 132 in the vertical direction DR3. In FIG. 3, the gate contact CB is illustrated as being formed as a single layer, but the present disclosure is not limited thereto. For example, in other embodiments, the gate contact CB may be formed as a multilayer. In at least some embodiments, the top surface of the gate contact CB may be formed on the same plane as the top surfaces of the upper source/drain contact UCA and the first upper interlayer insulating layer 150, but the present disclosure is not limited thereto. The gate contact CB may include a conductive material.

The bottom source/drain contact BCA may be disposed between the second and third gate electrodes G2 and G3. The bottom source/drain contact BCA may be disposed below the second source/drain region SD2. The bottom source/drain contact BCA may be electrically connected to the second source/drain region SD2 by penetrating the lower interlayer insulating layer 100 and the insulating pattern 101 in the vertical direction DR3. In at least one example, the bottom source/drain contact BCA may be formed as a single layer, but the present disclosure is not limited thereto. For example, in other embodiments, the bottom source/drain contact BCA may be formed as a multilayer.

In at one example, the top surface of the bottom source/drain contact BCA may be formed lower than the top surface of the insulating pattern 101. For example, both sidewalls, in the first horizontal direction DR1, of the bottom source/drain contact BCA may be in contact with the insulating pattern 101 and the lower interlayer insulating layer 100. In at least one example, the bottom surface of the bottom source/drain contact BCA may be formed on the same plane as the bottom surface of the first sacrificial pattern 103. For example, the bottom surface of the bottom source/drain contact BCA may be formed on the same plane as the bottom surface of the lower interlayer insulating layer 100, but the present disclosure is not limited thereto. For example, in some embodiments, the lower interlayer insulating layer 100 may be disposed on the bottom surface of the bottom source/drain contact BCA. The bottom source/drain contact BCA may include a conductive material.

The bottom silicide layer BSL may be disposed between the bottom source/drain contact BCA and the second source/drain region SD2. The bottom silicide layer BSL may be disposed along the boundary between the bottom source/drain contact BCA and the second source/drain region SD2. The bottom silicide layer BSL may include, for example, a metal silicide material.

The second etch stop layer 160 may be disposed on the top surfaces of the upper source/drain contact UCA, the first, second, and third capping patterns 131, 132, and 133, and the first upper interlayer insulating layer 150. In FIGS. 2 and 3, the second etch stop layer 160 is illustrated as being formed as a single layer, but the present disclosure is not limited thereto. For example, in other embodiments, the second etch stop layer 160 may be formed as a multilayer. The second etch stop layer 160 may include, for example, at least one of aluminum oxide, aluminum nitride, hafnium oxide, zirconium oxide, silicon oxide, silicon nitride, silicon oxynitride, and a low-k material. The second upper interlayer insulating layer 170 may be disposed on the second etch stop layer 160. The second upper interlayer insulating layer 170 may include an electrically insulative material, such as at least one of silicon oxide, silicon nitride, silicon oxynitride, and a low-k material.

The first via V1 may be connected to the upper source/drain contact UCA by penetrating the second upper interlayer insulating layer 170 and the second etch stop layer 160 in the vertical direction DR3. Similarly, the second via V2 may be connected to the gate contact CB by penetrating the second upper interlayer insulating layer 170 and the second etch stop layer 160 in the vertical direction DR3. Thus, an electrical path may be respectively formed between the first via V1 and a source/drain region (e.g., the first source/drain region SD1) and between the second via V2 and a gate electrode (e.g., the second gate electrode G2). In FIGS. 2 and 3, the first and second vias V1 and V2 are illustrated as being formed as single layers, but the present disclosure is not limited thereto. For example, in other embodiments, the first and second vias V1 and V2 may be formed as multilayers. The first and second vias V1 and V2 may include a conductive material.

A method of fabricating a semiconductor device according to some embodiments of the present disclosure will hereinafter be described with reference to FIGS. 2 through 24.

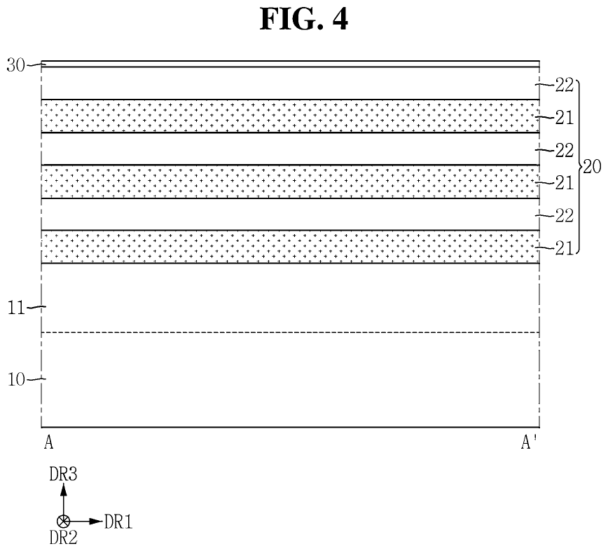

FIGS. 4 through 24 are cross-sectional views for explaining intermediate steps of a method of fabricating a semiconductor device according to some embodiments of the present disclosure.

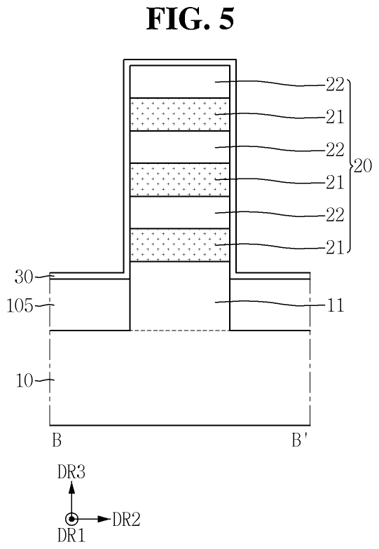

Referring to FIGS. 4 and 5, a substrate 10 may be provided. The substrate 10 may be a Si substrate or a silicon-on-insulator (SOI) substrate. Alternatively, the substrate 10 may include SiGe, silicon germanium-on-insulator (SGOI), indium antimonide, lead telluride compounds, indium arsenide, indium phosphide, gallium arsenide, or gallium antimonide, but the present disclosure is not limited thereto.

Thereafter, a stacked structure 20 may be formed on the top surface of the substrate 10. The stacked structure 20 may include first semiconductor layers 21 and second semiconductor layers 22, which are stacked on the top surface of the substrate 10, such that the second semiconductor layers 22 alternate with the first semiconductor layers 21. In at least one example, the first semiconductor layers 21 may be formed at the top of the stacked structure 20, and the second semiconductor layers 22 may be formed at the bottom of the second semiconductor layer 22. However, the present disclosure is not limited to this. For example, in other embodiments, the first semiconductor layers 21 may also be formed at both the top and bottom of the stacked structure 20. The first semiconductor layers 21 may include, for example, SiGe. The second semiconductor layers 22 may include, for example, Si.

Thereafter, part of the stacked structure 20 may be etched. During the etching of the stacked structure 20, part of the substrate 10 may also be etched. Through this etching process, an active pattern 11 may be defined on the top surface of the substrate 10, below the stacked structure 20. The active pattern 11 may protrude from the top surface of the substrate 10 in the vertical direction DR3. The active pattern 11 may extend in the first horizontal direction DR1.

Thereafter, a field insulating layer 105 may be formed on the top surface of the substrate 10. The field insulating layer 105 may surround at least a portion of the sidewalls of the active pattern 11. For example, the top surface of the active pattern 11 may be formed higher than the top surface of the field insulating layer 105. Thereafter, a pad oxide layer 30 may be formed to cover the top surface of the field insulating layer 105, the exposed sidewalls of the active pattern 11, and the sidewalls and top surface of the stacked structure 20. For example, the pad oxide layer 30 may be conformally formed. The pad oxide layer 30 may include, for example, SiO₂.

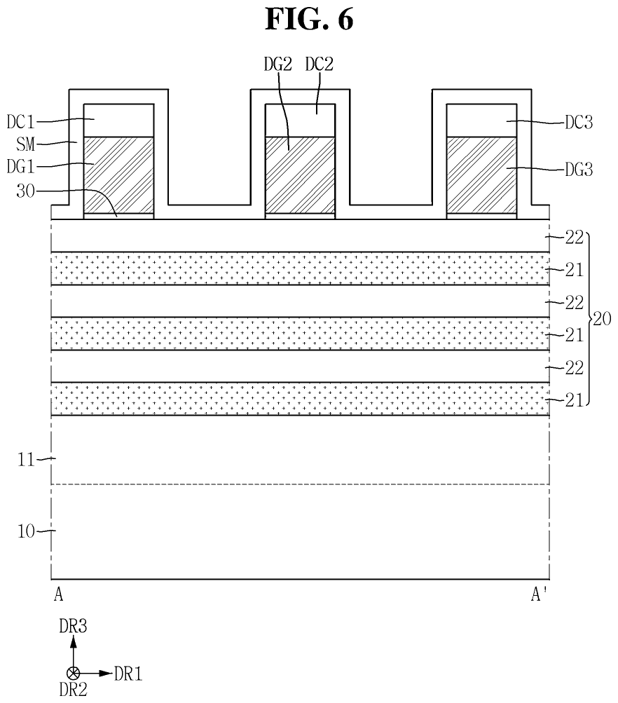

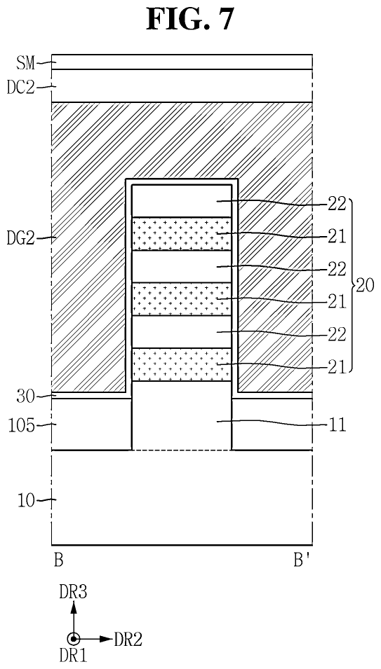

Referring to FIGS. 6 and 7, first, second, and third dummy gates DG1, DG2, and DG3, which extend in the second horizontal direction DR2, and first, second, and third dummy capping patterns DC1, DC2, and DC3, which also extend in the second horizontal direction DR2, may be formed on the pad oxide layer 30, on the stacked structure 20 and the field insulating layer 105. Specifically, the second dummy gate DG2 may be spaced apart from the first dummy gate DG1 in the first horizontal direction DR1, and the third dummy gate DG3 may be spaced from the second dummy gate DG2 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3.

During the formation of the first, second, and third dummy gates DG1, DG2, and DG3 and the first, second, and third dummy capping patterns DC1, DC2, and DC3, the entire pad oxide layer 30, except for portions that overlap with the first, second, and third dummy gates DG1, DG2, and DG3 in the vertical direction DR3, may be removed.

Thereafter, a spacer material layer SM may be formed to cover the sidewalls and top surfaces of the first, second, and third dummy gates DG1, DG2, and DG3, the first, second, and third dummy capping patterns DC1, DC2, and DC3, the exposed sidewalls and top surfaces of the stacked structure 20, and the top surface of the field insulating layer 105. For example, the spacer material layer SM may be conformally formed. The spacer material layer SM may include, for example, SiN, SiON, SiO₂, SiOCN, SiBN, SiOBN, SiOC, and/or a combination thereof.

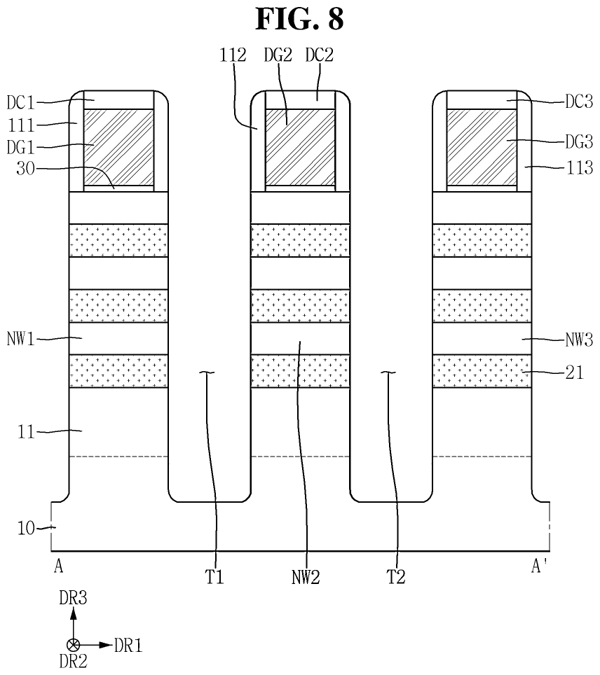

Referring to FIG. 8, first and second trenches T1 and T2 may be formed by etching the stacked structure 20 and the active pattern 11 using the first, second, and third dummy gates DG1, DG2, and DG3 and the first, second, and third dummy capping patterns DC1, DC2, and DC3 as a mask. The first trench T1 may be formed on a first side of the second dummy gate DG2. That is, the first trench T1 may be formed between the first and second dummy gates DG1 and DG2. Additionally, the second trench T2 may be formed on a second side of the second dummy gate DG2 that is opposite to the first side of the second dummy gate DG2 in the first horizontal direction DR1. That is, the second trench T2 may be formed between the second and third dummy gates DG2 and DG3.

During the formation of the first and second trenches T1 and T2, parts of the first, second, and third dummy capping patterns DC1, DC2, and DC3 and parts of the spacer material layer SM on the top surfaces of the first, second, and third dummy capping patterns DC1, DC2, and DC3 may be removed. Parts of the spacer material layer SM that remain on the sidewalls of each of the first, second, and third dummy capping patterns DC1, DC2, and DC3 and on the sidewalls of each of the first, second, and third dummy gates DG1, DG2, and DG3 may be defined as the first gate spacers 111, the second gate spacers 112, and the third gate spacers 113.

For example, the second semiconductor layers 22 that remain below the first dummy gate DG1 on the active pattern 11 after the formation of the first and second trenches T1 and T2 may be defined as the first plurality of nanosheets NW1. For example, the second semiconductor layers 22 that remain below the second dummy gate DG2 on the active pattern 11 after the formation of the first and second trenches T1 and T2 may be defined as the second plurality of nanosheets NW1. For example, the second semiconductor layers 22 that remain below the third dummy gate DG3 on the active pattern 11 after the formation of the first and second trenches T1 and T2 may be defined as third plurality of nanosheets NW3.

For example, the first trench T1 may extend into the substrate 10. That is, the bottom surface of the first trench T1 may be defined by the substrate 10. For example, the sidewalls, in the first horizontal direction DR1, of the first trench T1 may have a continuous slope profile. That is, sidewalls, in the first horizontal direction DR1, of the first plurality of nanosheets NW1, the first semiconductor layers 21, and the active pattern 11, exposed through the first trench T1, may all be aligned. Additionally, sidewalls, in the first horizontal direction DR1, of the second plurality of nanosheets NW2, the first semiconductor layers 21, and the active pattern 11, exposed through the first trench T1, may all be aligned.

For example, the second trench T2 may extend into the substrate 10. That is, the bottom surface of the second trench T2 may be defined by the substrate 10. For example, the sidewalls, in the first horizontal direction DR1, of the second trench T2 may have a continuous slope profile. That is, sidewalls, in the first horizontal direction DR1, of the second plurality of nanosheets NW2, the first semiconductor layers 21, and the active pattern 11, exposed through the second trench T2, may be aligned. Additionally, sidewalls, in the first horizontal direction DR1, of the third plurality of nanosheets NW3, the first semiconductor layers 21, and the active pattern 11, exposed through the second trench T2, may also be aligned.

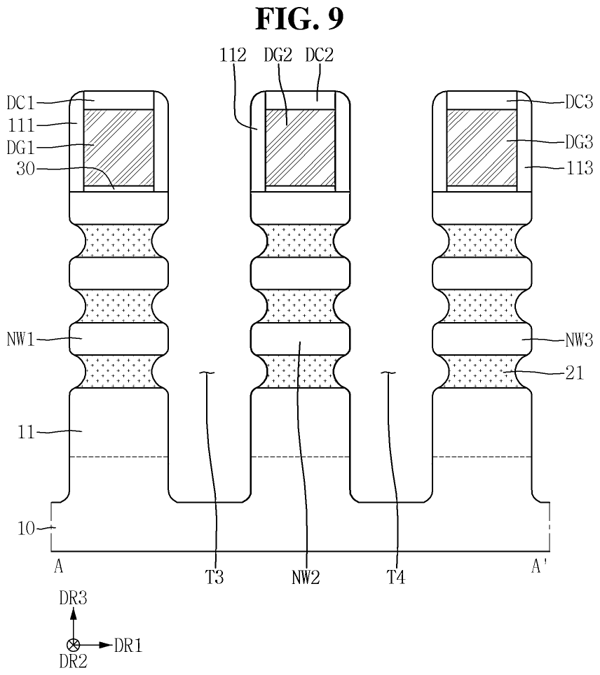

Referring to FIG. 9, parts of the sidewalls, in the first horizontal direction DR1, of the first semiconductor layers 21, exposed through the first trench T1, may be partially etched to form the third trench T3 (e.g., thereby converting the first trench T1 to the third trench T3). For example, parts of the sidewalls, in the first horizontal direction DR1, of the first semiconductor layer 21, exposed through the first trench T1, between the active pattern 11 and the lowermost nanosheet of the first plurality of nanosheet NW1, may be etched. Additionally, parts of the sidewalls, in the first horizontal direction DR1, of the first semiconductor layers 21, exposed through the first trench T1, between the first plurality of nanosheets NW1 that are adjacent to one another, may be etched. For example, parts of the sidewalls, in the first horizontal direction DR1, of the first semiconductor layers 21, exposed through the first trench T1, between the active pattern 11 and the lowermost nanosheet of the second plurality of nanosheet NW2, may be etched. Moreover, parts of the sidewalls, in the first horizontal direction DR1, of the first semiconductor layers 21, exposed through the first trench T1, between the second plurality of nanosheets NW2 that are adjacent to one another, may be etched.

Also, parts of the sidewalls, in the first horizontal direction DR1, of the first semiconductor layers 21, exposed through the second trench T2 may be partially etched to form the fourth trench T4. For example, parts of the sidewalls, in the first horizontal direction DR1, of the first semiconductor layer 21, exposed through the second trench T2, between the active pattern 11 and the lowermost nanosheet of the second plurality of nanosheet NW2, may be etched. Furthermore, parts of the sidewalls, in the first horizontal direction DR1, of the first semiconductor layers 21, exposed through the second trench T2, between the second plurality of nanosheets NW2 that are adjacent to one another, may be etched. For example, parts of the sidewalls, in the first horizontal direction DR1, of the first semiconductor layers 21, exposed through the second trench T2, between the active pattern 11 and the lowermost nanosheet of the third plurality of nanosheet NW3, may be etched. Additionally, parts of the sidewalls, in the first horizontal direction DR1, of the first semiconductor layers 21, exposed through the second trench T2, between the third plurality of nanosheets NW3 that are adjacent to one another, may be etched.

For example, the sidewalls, in the first horizontal direction DR1, of the first semiconductor layers 21 disposed between the first plurality of nanosheets NW1 that are adjacent to one another may be concavely formed toward the centers of the first semiconductor layers 21 compared to the sidewalls, in the first horizontal direction DR1, of the first plurality of nanosheets NW1. Similarly, the sidewalls, in the first horizontal direction DR1, of the first semiconductor layers 21 disposed between the second plurality of nanosheets NW2 that are adjacent to one another may be concavely formed toward the centers of the first semiconductor layers 21 compared to the sidewalls, in the first horizontal direction DR1, of the second plurality of nanosheets NW2. The sidewalls, in the first horizontal direction DR1, of the first semiconductor layers 21 disposed between the third plurality of nanosheets NW3 that are adjacent to one another may be concavely formed toward the centers of the first semiconductor layers 21 compared to sidewalls, in the first horizontal direction DR1, of the third plurality of nanosheets NW3.

For example, a region including the first trench T1 and the part from which the sidewalls of the first semiconductor layers 21 have been partially etched may be defined as a third trench T3. That is, the third trench T3 may be formed on first sides of the first semiconductor layers 21 disposed between the second plurality of nanosheets NW2 that are adjacent to one another. For example, a region including the second trench T2 and the part from which the sidewalls of the first semiconductor layers 21 have been partially etched may be defined as a fourth trench T4. That is, the fourth trench T4 may be formed on second sides of the first semiconductor layers 21 disposed between the second plurality of nanosheets NW2 that are adjacent to one another. Here, the second sides of the first semiconductor layers 21 are defined as being opposite to the first sides of the first semiconductor layers 21 in the first horizontal direction DR1.

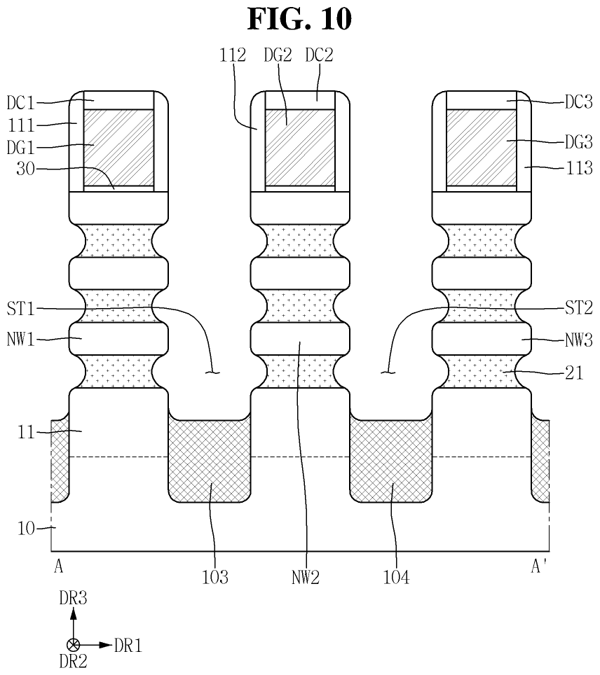

Referring to FIG. 10, a first sacrificial pattern 103 may be formed inside the third trench T3. The first sacrificial pattern 103 may fill part of the third trench T3. For example, part of the third trench T3 that remains unfilled on the top surface of the first sacrificial pattern 103 may be defined as a first source/drain trench ST1. Also, a second sacrificial pattern 104 may be formed inside the fourth trench T4. The second sacrificial pattern 104 may fill part of the fourth trench T4. For example, part of the fourth trench T4 that remains unfilled on the top surface of the second sacrificial pattern 104 may be defined as a second source/drain trench ST2. For example, the first and second sacrificial patterns 103 and 104 may be formed by epitaxial growth. For example, the first and second sacrificial patterns 103 and 104 may be formed through the same fabricating process.

For example, the top surfaces of the first and second sacrificial patterns 103 and 104 may be formed lower than the top surface of the active pattern 11. For example, the sidewalls, in the first horizontal direction DR1, of each of the first and second sacrificial patterns 103 and 104 may be in contact with the active pattern 11 and the substrate 10. The bottom surfaces of the first and second sacrificial patterns may be in contact with the substrate 10. For example, the first and second sacrificial patterns 103 and 104 may include the same material. For example, the first and second sacrificial patterns 103 and 104 may include SiGe.

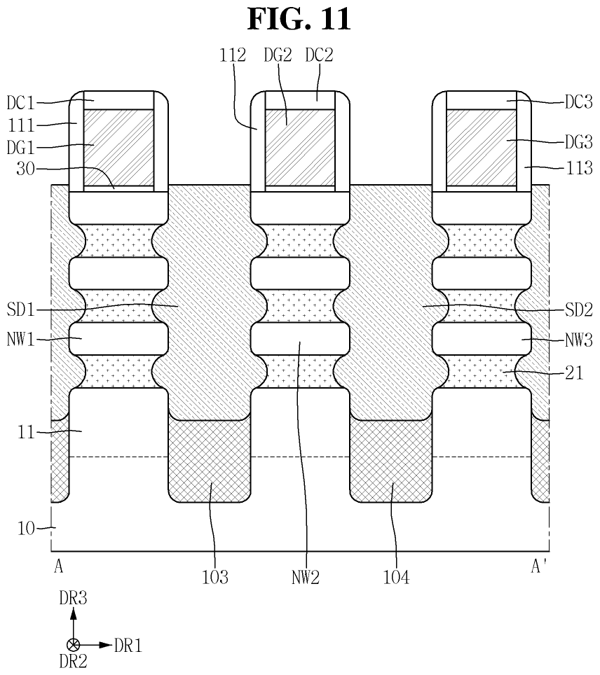

Referring to FIG. 11, a first source/drain region SD1 may be formed inside the first source/drain trench ST1. For example, the bottom surface of the first source/drain region SD1 may be in contact with the first sacrificial pattern 103. For example, the first source/drain region SD1 may be in contact with the sidewalls, in the first horizontal direction DR1, of the first plurality of nanosheets NW1. For example, the first source/drain region SD1 may be in contact with the first sidewalls, in the first horizontal direction DR1, of the second plurality of nanosheets NW2.

Additionally, a second source/drain region SD2 may be formed inside the second source/drain trench ST2. For example, the bottom surface of the second source/drain region SD2 may be in contact with the second sacrificial pattern 104. For example, the second source/drain region SD2 may be in contact with the second sidewalls of the second plurality of nanosheets NW2 that are opposite to the first sidewalls of the second plurality of nanosheets NW2 in the first horizontal direction DR1. For example, the second source/drain region SD2 may be in contact with the sidewalls, in the first horizontal direction DR1, of the third plurality of nanosheets NW3.

For example, at least parts of the first source/drain region SD1 may be convexly formed toward the first semiconductor layers 21 between the insulating pattern 101 and the lowermost nanosheet of the first plurality of nanosheet NW1. That is, at least parts of the first source/drain region SD1 may be disposed between the insulating pattern 101 and the lowermost nanosheet of the first plurality of nanosheet NW1. For example, the first source/drain region SD1 may be convexly formed toward the first semiconductor layers 21 between the first plurality of nanosheets NW1 that are adjacent to one another. That is, at least parts of the first source/drain region SD1 may be disposed between the first plurality of nanosheets NW1 that are adjacent to one another.

For example, at least parts of the first source/drain region SD1 may be convexly formed toward the first semiconductor layers 21 between the insulating pattern 101 and the lowermost nanosheet of the second plurality of nanosheet NW2. That is, at least parts of the first source/drain region SD1 may be disposed between the insulating pattern 101 and the lowermost nanosheet of the second plurality of nanosheet NW2. For example, the first source/drain region SD1 may be convexly formed toward the first semiconductor layers 21 between the second plurality of nanosheets NW2 that are adjacent to one another. That is, at least parts of the first source/drain region SD1 may be disposed between the second plurality of nanosheets NW2 that are adjacent to one another.

For example, at least parts of the second source/drain region SD2 may be convexly formed toward the first semiconductor layers 21 between the insulating pattern 101 and the lowermost nanosheet of the second plurality of nanosheet NW2. That is, at least parts of the second source/drain region SD2 may be disposed between the insulating pattern 101 and the lowermost nanosheet of the second plurality of nanosheet NW2. For example, the second source/drain region SD2 may be convexly formed toward the first semiconductor layers 21 between the second plurality of nanosheets NW2 that are adjacent to one another. That is, at least parts of the second source/drain region SD2 may be disposed between the second plurality of nanosheets NW2 that are adjacent to one another.

For example, at least parts of the second source/drain region SD2 may be convexly formed toward the first semiconductor layers 21 between the insulating pattern 101 and the lowermost nanosheet of the third plurality of nanosheet NW3. That is, at least parts of the second source/drain region SD2 may be disposed between the insulating pattern 101 and the lowermost nanosheet of the third plurality of nanosheet NW3. For example, the second source/drain region SD2 may be convexly formed toward the first semiconductor layers 21 between the third plurality of nanosheets NW3 that are adjacent to one another. That is, at least parts of the second source/drain region SD2 may be disposed between the third plurality of nanosheets NW3 that are adjacent to one another.

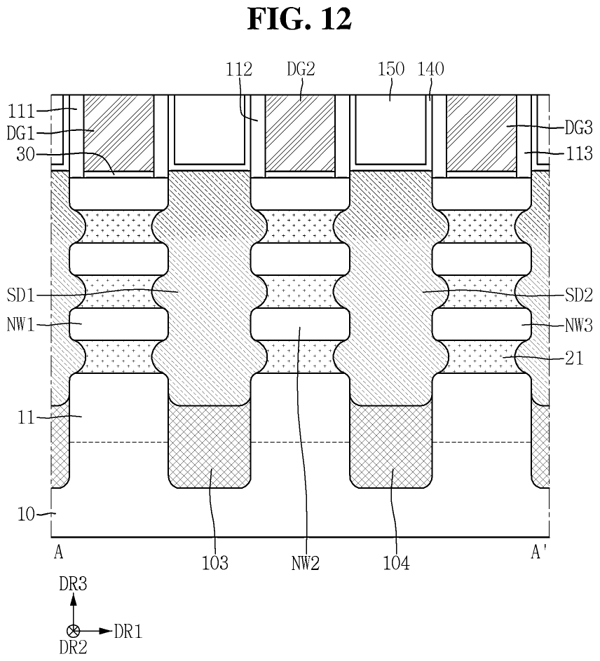

Referring to FIG. 12, a first etch stop layer 140 may be formed on the exposed sidewalls of each of the first, second, and third gate spacers 111, 112, and 113, the exposed top surfaces of the first, second, and third dummy capping patterns DC1, DC2, and DC3, and the exposed surfaces of the first and second source/drain regions SD1 and SD2. Thereafter, a first upper interlayer insulating layer 150 may be formed on the first etch stop layer 140. Thereafter, the top surfaces of the first, second, and third dummy gates DG1, DG2, and DG3 may be exposed through a planarization process. The first etch stop layer 140 may include a material selected based on an etch selectivity compared to, e.g., the first, second, and third dummy gates DG1, DG2, and DG3, and/or the first semiconductor layers 21.

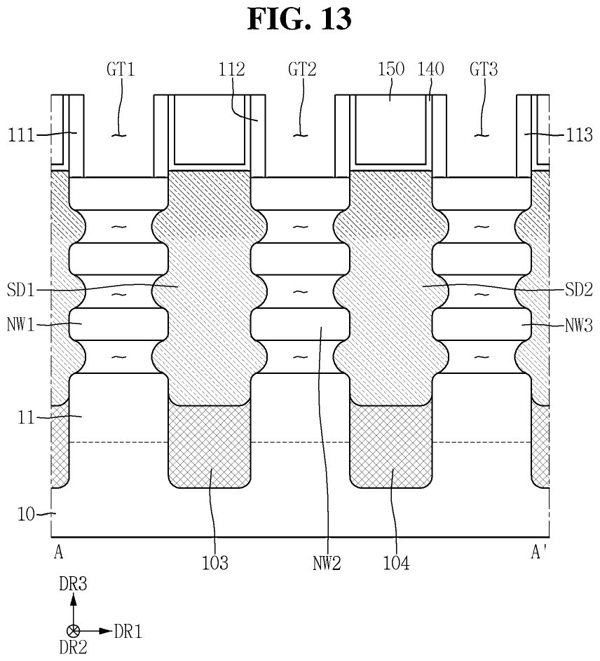

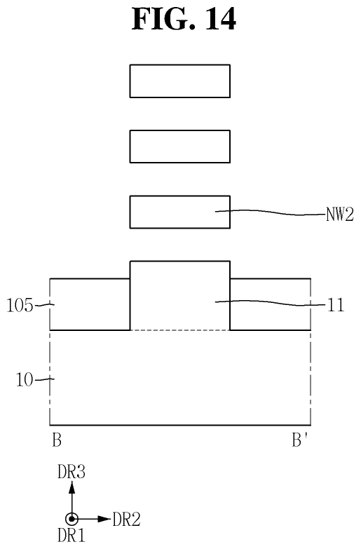

Referring to FIGS. 13 and 14, the first, second, and third dummy gates DG1, DG2, and DG3, the pad oxide layer 30, and the first semiconductor layers 21 may each be removed. The part from which the first dummy gate DG1, the pad oxide layer 30, and the first semiconductor layers 21 have been removed may be defined as a first gate trench GT1. Similarly, the part from which the second dummy gate DG2, the pad oxide layer 30, and the first semiconductor layers 21 have been removed may be defined as a second gate trench GT2. The part from which the third dummy gate DG3, the pad oxide layer 30, and the first semiconductor layers 21 have been removed may be defined as a third gate trench GT3.

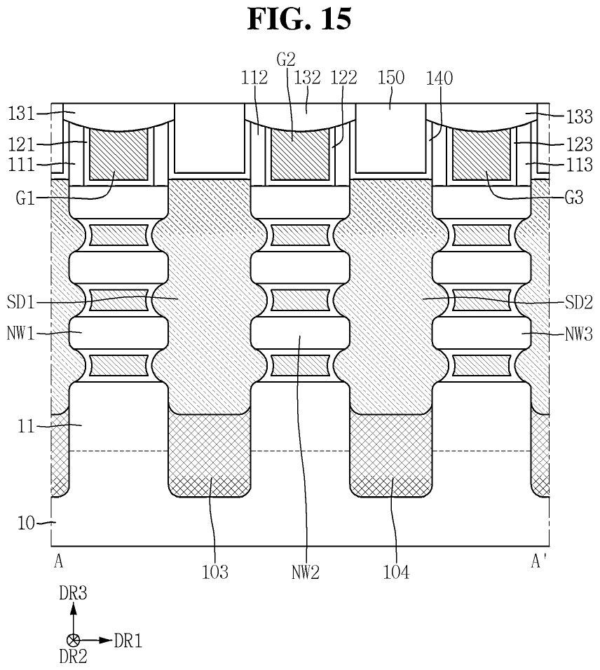

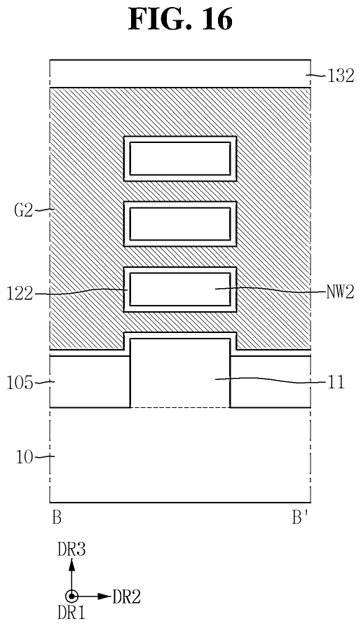

Referring to FIGS. 15 and 16, a first gate insulating layer 121, a first gate electrode G1, and a first capping pattern 131 may be sequentially formed in the first gate trench GT1. Similarly, a second gate insulating layer 122, a second gate electrode G2, and a second capping pattern 132 may be sequentially formed in the second gate trench GT2, and a third gate insulating layer 123, a third gate electrode G3, and a third capping pattern 133 may be sequentially formed in the third gate trench GT3. For example, the first gate electrode G1 may surround the first plurality of nanosheets NW1, the second gate electrode G2 may surround the second plurality of nanosheets NW2, and the third gate electrode G3 may surround the third plurality of nanosheets NW2.

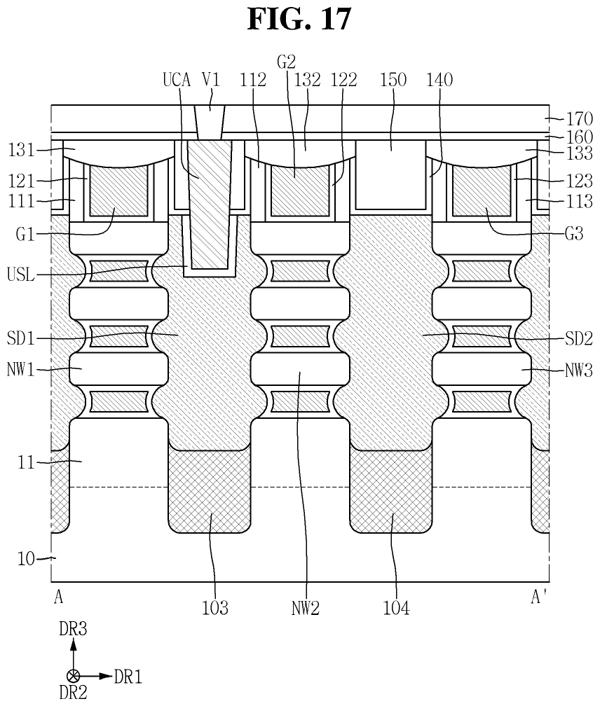

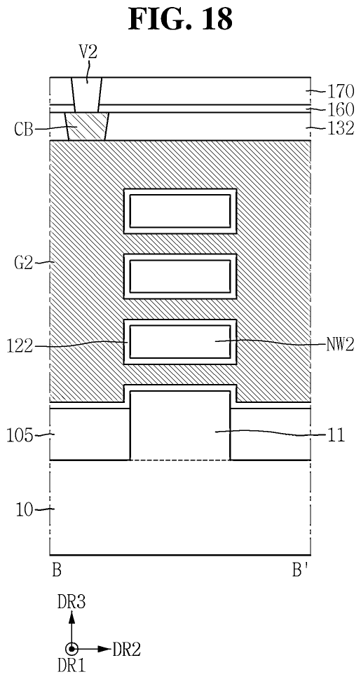

Referring to FIGS. 17 and 18, an upper source/drain contact UCA may be formed on the first source/drain region SD1. The upper source/drain contact UCA may extend into the first source/drain region SD1 by penetrating the first upper interlayer insulating layer 150 and the first etch stop layer 140 in the vertical direction DR3. Additionally, an upper silicide layer USL may be formed between the first source/drain region SD1 and the upper source/drain contact UCA. Furthermore, a gate contact CB, which is connected to the second gate electrode G2 by penetrating the second capping pattern 132 in the vertical direction DR3, may be formed.

Thereafter, a second etch stop layer 160 and a second upper interlayer insulating layer 170 may be sequentially formed on the top surfaces of the first upper interlayer insulating layer 150, the first, second, and third capping patterns 131, 132, and 133, and the upper source/drain contact UCA. Thereafter, a first via V1, which is connected to the upper source/drain contact UCA by penetrating the second etch stop layer 160 and the second upper interlayer insulating layer 170 in the vertical direction DR3, may be formed. Similarly, a second via V2, which is connected to the gate contact CB by penetrating the second etch stop layer 160 and the second upper interlayer insulating layer 170 in the vertical direction DR3, may be formed.

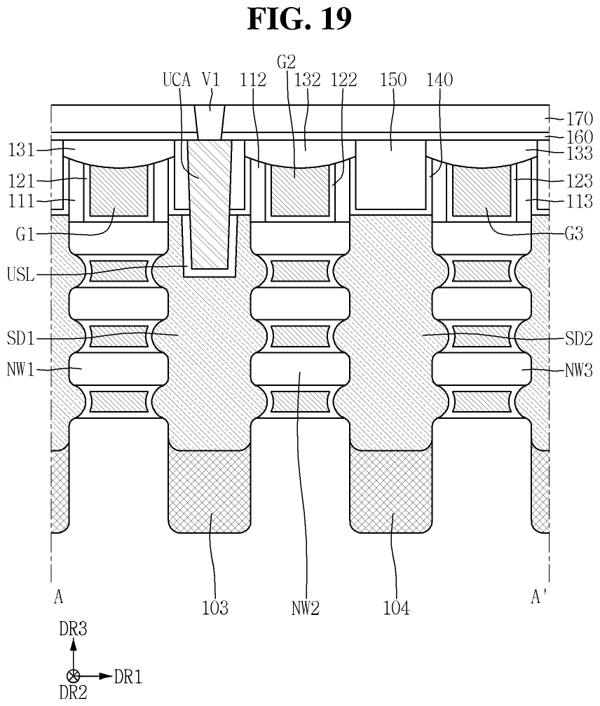

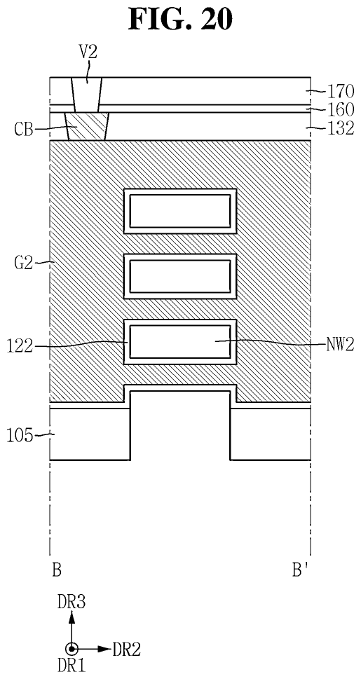

Referring to FIGS. 19 and 20, parts of the substrate 10 and the active pattern 11 may be etched. As a result, parts of the first, second, and third gate insulating layers 121, 122, and 123, parts of the first and second source/drain regions SD1 and SD2, part of the field insulating layer 105, and parts of the first and second sacrificial patterns 103 and 104 may be exposed.

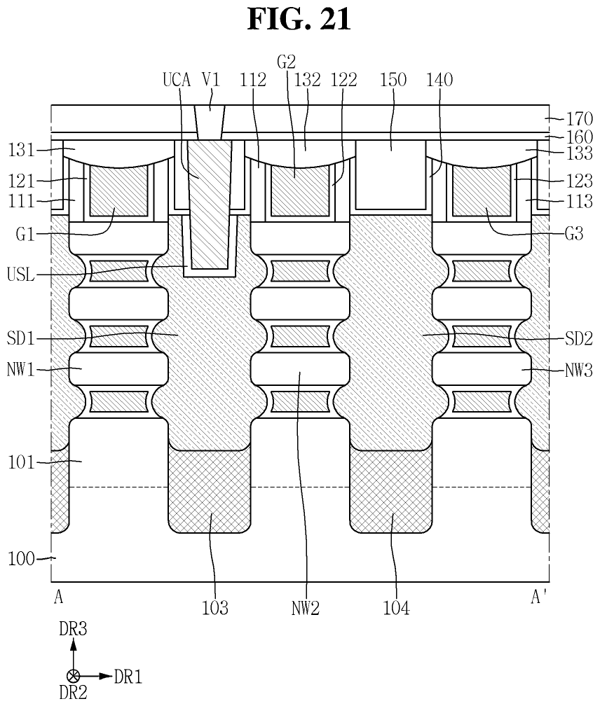

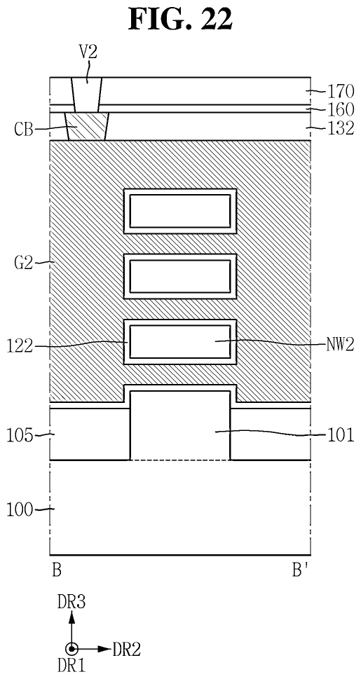

Referring to FIGS. 21 and 22, a lower interlayer insulating layer 100 and an insulating pattern 101 may be formed in the part from which the substrate 10 and the active pattern 11 have been etched. For example, the insulating pattern 101 may be formed in the part from which the active pattern 11 has been etched. The insulating pattern 101 may be in contact with the first, second, and third gate insulating layers 121, 122, and 123, the first and second source/drain regions SD1 and SD2, the field insulating layer 105, and the first and second sacrificial patterns 103 and 104. The insulating pattern 101 may surround parts of the sidewalls of each of the first and second sacrificial patterns 103 and 104.

Additionally, a lower interlayer insulating layer 100 may be formed in the part from which the substrate 10 has been etched. The lower interlayer insulating layer 100 may be in contact with the field insulating layer 105 and each of the first and second sacrificial patterns 103 and 104. The lower interlayer insulating layer 100 may surround parts of the sidewalls of each of the first and second sacrificial patterns 103 and 104. The lower interlayer insulating layer 100 may cover the bottom surfaces of the first and second sacrificial patterns 103 and 104.

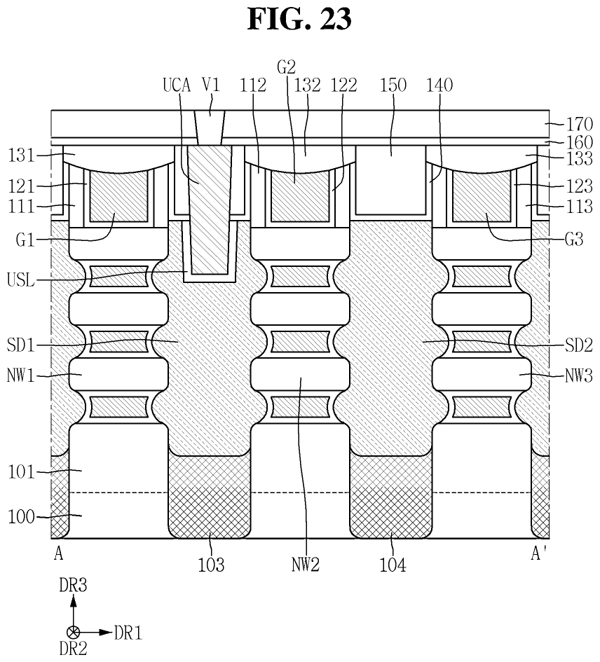

Referring to FIG. 23, part of the lower interlayer insulating layer 100 may be etched by performing a planarization process. As a result of the planarization process, the bottom surfaces of the first and second sacrificial patterns 103 and 104 may be exposed.

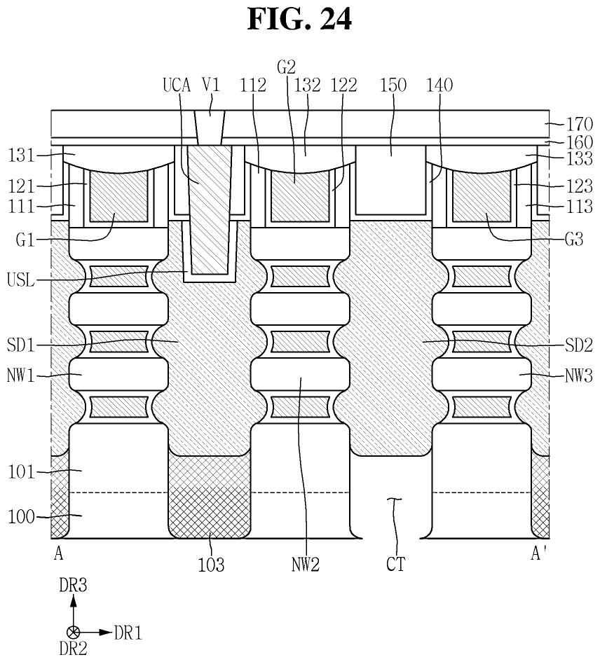

Referring to FIG. 24, the second sacrificial pattern 104 may be removed. For example, after the formation of a protective layer on the bottom surface of the first sacrificial pattern 103, the second sacrificial pattern 104 may be selectively removed. After the removal of the second sacrificial pattern 104, the protective layer formed on the bottom surface of the first sacrificial pattern 103 may be removed. The part from which the second sacrificial pattern 104 has been removed may be defined as a contact trench CT. For example, the sidewalls of the contact trench CT may be defined by the insulating pattern 101 and the lower interlayer insulating layer 100. For example, the top surface of the contact trench CT may be defined as the bottom surface of the second source/drain region SD2. That is, the contact trench CT may expose the bottom surface of the second source/drain region SD2.

Referring to FIGS. 2 and 3, a bottom source/drain contact BCA may be formed inside the contact trench CT. For example, the bottom surface of the bottom source/drain contact BCA may be formed on the same plane as the bottom surface of the lower interlayer insulating layer 100. For example, the bottom source/drain contact BCA may be formed as a single layer. For example, both sidewalls, in the first horizontal direction DR1, of the bottom source/drain contact BCA may be in contact with both the insulating pattern 101 and the lower interlayer insulating layer 100. Additionally, a bottom silicide layer BSL may be formed between the bottom source/drain contact BCA and the second source/drain region SD2. In this manner, the semiconductor device of FIGS. 2 and 3 may be obtained.

According to the method of FIGS. 4 through 24, before the formation of the first and second sacrificial patterns 103 and 104, parts of the sidewalls of each of the first semiconductor layers 21 may be etched. During the epitaxial growth of the first and second sacrificial patterns 103 and 104, the epitaxial growth of the sidewalls of each of the first semiconductor layers 21 may be suppressed, thereby preventing the first semiconductor layers 21 from merging and thereby improving the reliability of a semiconductor device. In a semiconductor device obtained by the method of FIGS. 4 through 24, at least part of the second source/drain region SD2 may be disposed between the second plurality of nanosheets NW2 that are adjacent to one another, on the top surface of the bottom source/drain contact BCA.

A method of fabricating a semiconductor device according to some embodiments of the present disclosure will hereinafter be described with reference to FIGS. 2 and 25 through 28, focusing mainly on the differences from the method of FIGS. 4 through 24.

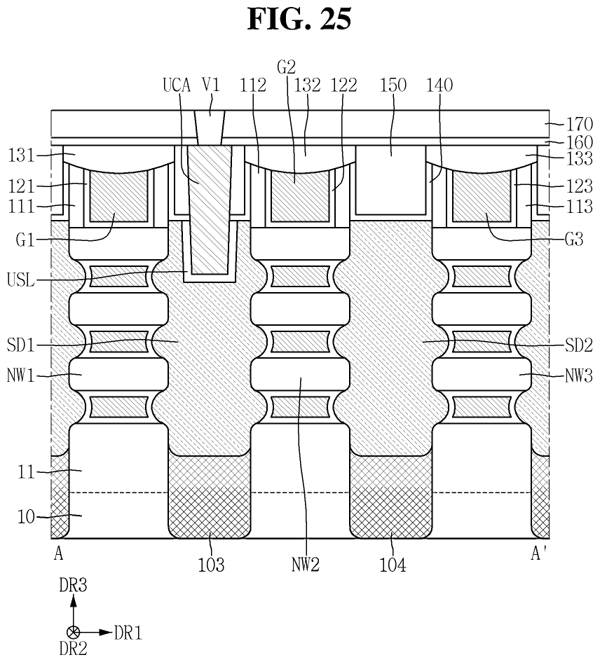

FIGS. 25 through 28 are cross-sectional views for explaining intermediate steps of a method of fabricating a semiconductor device according to other embodiments of the present disclosure.

Referring to FIG. 25, after the processes depicted in FIGS. 4 through 18, part of a substrate 10 may be etched by performing a planarization process. As a result of the planarization process, the bottom surfaces of the first and second sacrificial patterns 103 and 104 may be exposed.

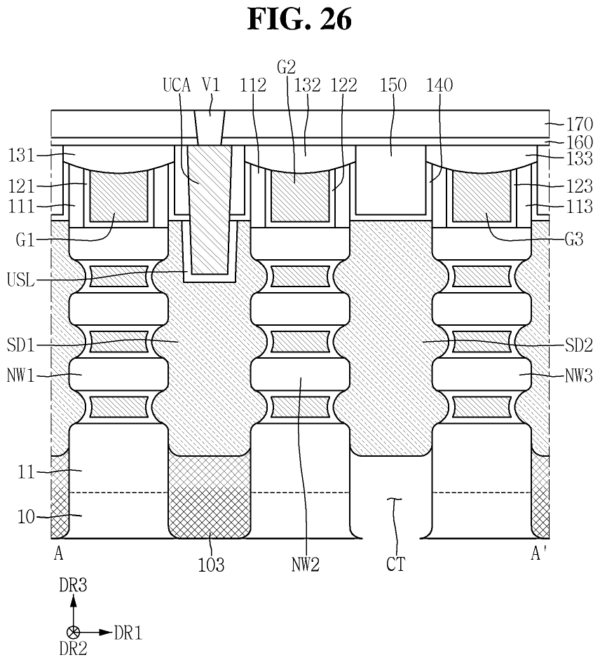

Referring to FIG. 26, the second sacrificial pattern 104 may be removed. For example, after the formation of a protective layer on the bottom surface of the first sacrificial pattern 103, the second sacrificial pattern 104 may be selectively removed. After the removal of the second sacrificial pattern 104, the protective layer formed on the bottom surface of the first sacrificial pattern 103 may be removed. The part from which the second sacrificial pattern 104 has been removed may be defined as a contact trench CT. For example, the sidewalls of the contact trench CT may be defined by an active pattern 11 and the substrate 10. For example, the top surface of the contact trench CT may be defined as the bottom surface of a second source/drain region SD2. That is, the contact trench CT may expose the bottom surface of the second source/drain region SD2.

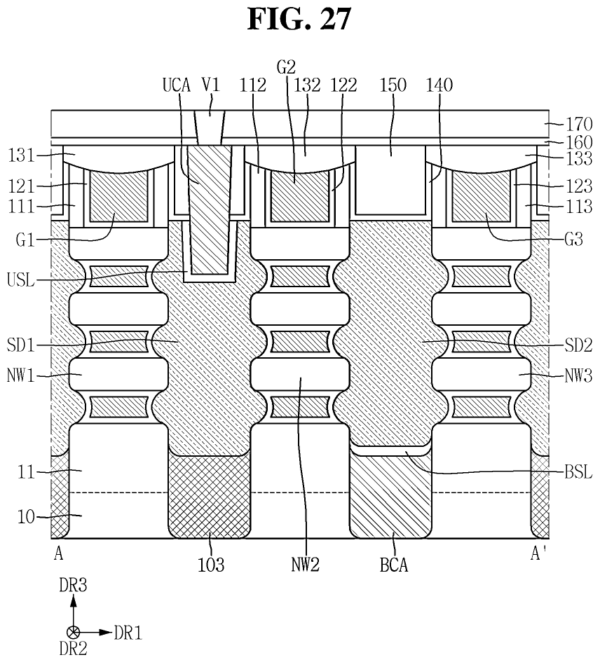

Referring to FIG. 27, a bottom source/drain contact BCA may be formed inside the contact trench CT. For example, the bottom surface of the bottom source/drain contact BCA may be formed on the same plane as the bottom surface of the substrate 10. For example, the bottom source/drain contact BCA may be formed as a single layer. For example, both sidewalls, in a first horizontal direction DR1, of the bottom source/drain contact BCA may be in contact with both an active pattern 11 and the substrate 10. Additionally, a bottom silicide layer BSL may be formed between the bottom source/drain contact BCA and the second source/drain region SD2.

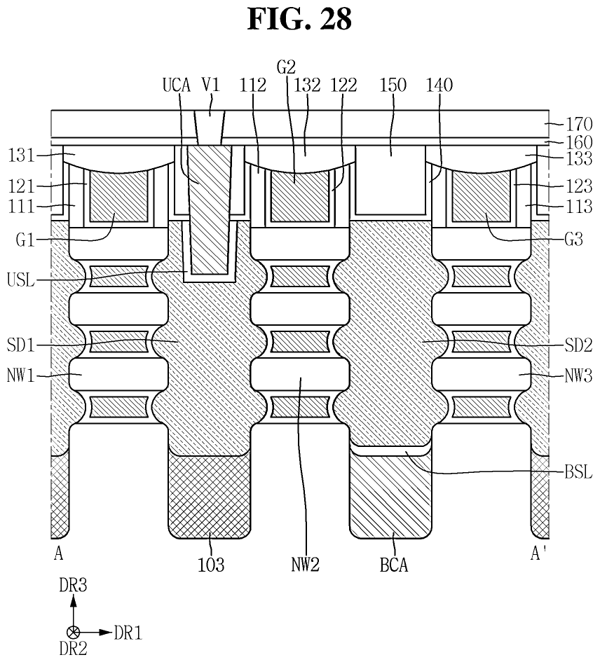

Referring to FIG. 28, the substrate 10 and the active pattern 11 may be removed. As a result, parts of first, second, and third gate insulating layers 121, 122, and 123, part of a first source/drain region SD1, part of the second source/drain region SD2, part of a field insulating layer 105, part of a first sacrificial pattern 103, and part of the bottom source/drain contact BCA may be exposed.

Referring to FIG. 2, a lower interlayer insulating layer 100 and an insulating pattern 101 may be formed in the part from which the substrate 10 and the active pattern 11 have been removed. For example, the insulating pattern 101 may be formed in the region where the active pattern 11 has been removed. The insulating pattern 101 may be in contact with each of the first, second, and third gate insulating layers 121, 122, and 123, the first and second source/drain regions SD1 and SD2, the field insulating layer 105, the first sacrificial pattern 103, and the bottom source/drain contact BCA. The insulating pattern 101 may surround parts of the sidewalls of each of the first sacrificial pattern 103 and the bottom source/drain contact BCA.

Additionally, the lower interlayer insulating layer 100 may be formed in the part from which the substrate 10 has been etched. The lower interlayer insulating layer 100 may be in contact with the field insulating layer 105, the first sacrificial pattern 103, and the bottom source/drain contact BCA. The lower interlayer insulating layer 100 may surround parts of the sidewalls of each of the first sacrificial pattern 103 and the bottom source/drain contact BCA. Moreover, the lower interlayer insulating layer 100 may cover the bottom surfaces of both the first sacrificial pattern 103 and the bottom source/drain contact BCA. Thereafter, a planarization process may be carried out where part of the lower interlayer insulating layer 100 may be etched. As a result of the planarization process, the bottom surfaces of the first sacrificial pattern 103 and the bottom source/drain contact BCA may be exposed. In this manner, the semiconductor device of FIG. 2 may be obtained.

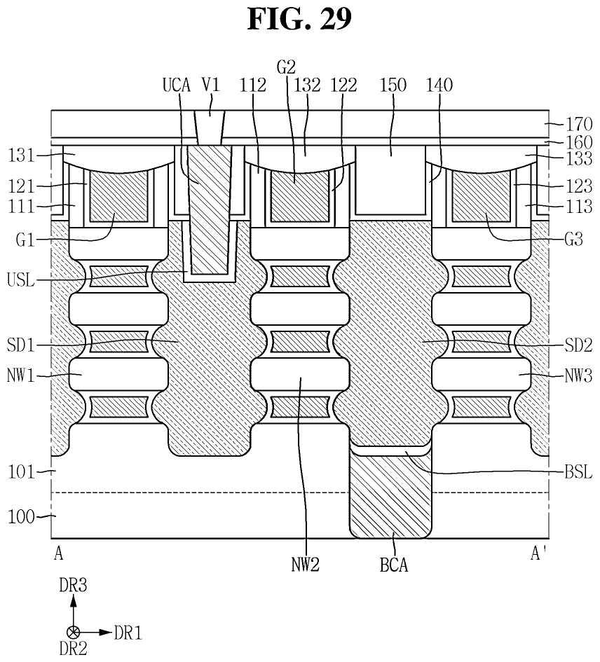

A semiconductor device according to other embodiments of the present disclosure will hereinafter be described with reference to FIG. 29, focusing mainly on the differences from the semiconductor device of FIGS. 1 through 3.

FIG. 29 is a cross-sectional view for explaining a semiconductor device according to other embodiments of the present disclosure.

Referring to FIG. 29, a first sacrificial pattern (“103” of FIG. 2) is not disposed below a first source/drain region SD1. For example, the bottom surface of the first source/drain region SD1 may be entirely in contact with an insulating pattern 101.

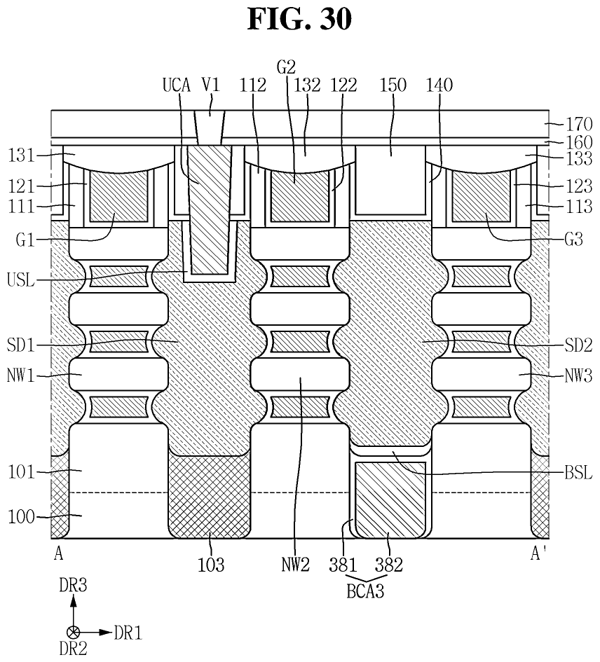

A semiconductor device according to other embodiments of the present disclosure will hereinafter be described with reference to FIG. 30, focusing mainly on the differences from the semiconductor device of FIGS. 1 through 3.

FIG. 30 is a cross-sectional view for explaining a semiconductor device according to other embodiments of the present disclosure.

Referring to FIG. 30, a bottom source/drain contact BCA3 may be formed as a double film.

For example, the bottom source/drain contact BCA3 may include a contact barrier layer 381 and a contact filling layer 382. For example, the contact barrier layer 381 may form the sidewalls and top surface of the bottom source/drain contact BCA3. The contact barrier layer 381 may be in contact with a lower interlayer insulating layer 100, an insulating pattern 101, and a bottom silicide layer BSL. The contact filling layer 382 may fill the gap between portions of the contact barrier layer 381. For example, the bottom surface of the contact filling layer 382 may be formed on the same plane as the bottom surface of a lower interlayer insulating layer 100.

For example, the contact barrier layer 381 may include a material such as Ta, TaN, Ti, TiN, Ru, Co, Ni, nickel boron (NiB), W, WN, tungsten carbonitride (WCN), Zr, zirconium nitride (ZrN), V, vanadium nitride (VN), Nb, NbN, Pt, Ir, or Rh. For example, the contact filling layer 382 may include a material such as Al, W, Co, Ru, or Mo. It at least one embodiment, the contact barrier layer 381 may prevent (and/or mitigate) diffusion to or from the contact filling layer 382.

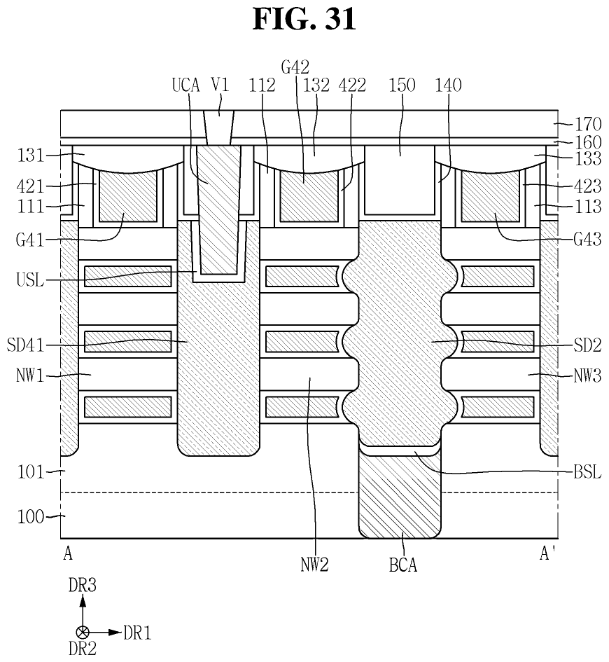

A semiconductor device according to other embodiments of the present disclosure will hereinafter be described with reference to FIG. 31, focusing mainly on the differences from the semiconductor device of FIGS. 1 through 3.

FIG. 31 is a cross-sectional view for explaining a semiconductor device according to other embodiments of the present disclosure.

Referring to FIG. 31, a first source/drain region SD41 is not convexly formed toward first and second gate electrodes G41 and G42, but a second source/drain region SD2 may be convexly formed toward both the second gate electrode G42 and a third gate electrode G43. That is, only the second source/drain region SD2, disposed on a bottom source/drain contact BCA, may be formed convexly toward adjacent gate electrodes.

For example, a first sacrificial pattern (“103” of FIG. 2) is not disposed below the first source/drain region SD41. For example, the bottom surface of the first source/drain region SD41 may be entirely in contact with an insulating pattern 101. For example, the first source/drain region SD41 is not disposed between the insulating pattern 101 and a lowermost nanosheet of the first plurality of nanosheet NW1. The first source/drain region SD41 is not disposed between the first plurality of nanosheets NW1 that are adjacent to one another. Additionally, the first source/drain region SD41 is not disposed between the insulating pattern 101 and a lowermost nanosheet of the second plurality of nanosheet NW2. The first source/drain region SD41 is not disposed between the second plurality of nanosheets NW2 that are adjacent to one another.

For example, the sidewalls, in a first horizontal direction DR1, of the first source/drain region SD41, which are in contact with the first plurality of nanosheets NW1, a first gate insulating layer 421, and the insulating pattern 101, may form a continuous slope profile. Additionally, the sidewalls, in the first horizontal direction DR1, of the first source/drain region SD41, which are in contact with the second plurality of nanosheets NW2, a second gate insulating layer 422, and the insulating pattern 101, may form a continuous slope profile. For example, the first source/drain region SD41 may be in contact with the first and second gate insulating layers 421 and 422. Moreover, the second source/drain region SD2 may be in contact with the second gate insulating layer 422 and a third gate insulating layer 423.

A method of fabricating a semiconductor device according to some embodiments of the present disclosure will hereinafter be described with reference to FIGS. 31 through 36, focusing mainly on the differences from the method of FIGS. 4 through 24.

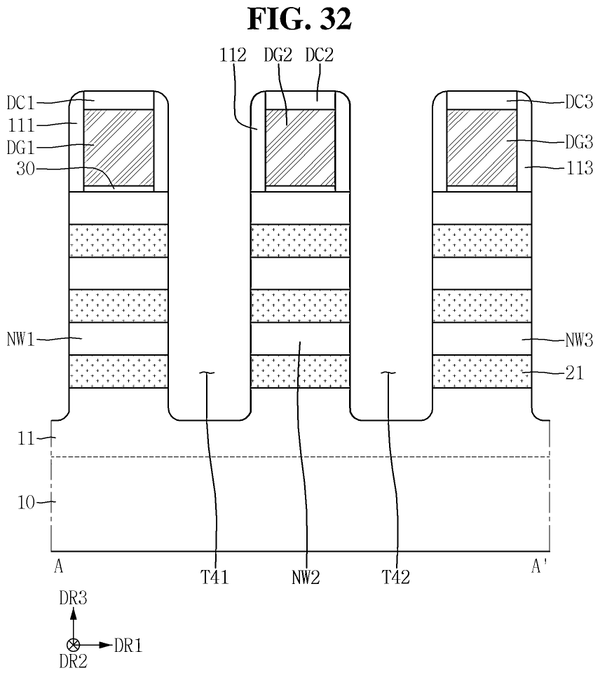

FIGS. 32 through 36 are cross-sectional views for explaining intermediate steps of a method of fabricating a semiconductor device according to other embodiments of the present disclosure.

Referring to FIG. 32, after the processes depicted in FIGS. 4 through 7, a stacked structure (“20” of FIG. 6) and an active pattern 11 may be etched using first, second, and third dummy gates DG1, DG2, and DG3 and first, second, and third dummy capping patterns DC1, DC2, and DC3 as a mask, thereby forming first and second trenches T41 and T42. The first trench T41 may be formed on a first side of the second dummy gate DG2. That is, the first trench T41 may be formed between the first and second dummy gates DG1 and DG2. Additionally, the second trench T42 may be formed on a second side of the second dummy gate DG2 that is opposite to the first side of the second dummy gate DG2 in a first horizontal direction DR1. That is, the second trench T42 may be formed between the second and third dummy gates DG2 and DG3.

During the formation of the first and second trenches T41 and T42, parts of the first, second, and third dummy capping patterns DC1, DC2, and DC3 and parts of a spacer material layer (“SM” of FIG. 6) that are formed on the top surfaces of the first, second, and third dummy capping patterns DC1, DC2, and DC3 may be removed. Parts of the spacer material layer SM that remain on the sidewalls of each of the first, second, and third dummy capping patterns DC1, DC2, and DC3 and the sidewalls of each of the first, second, and third dummy gates DG1, DG2, and DG3 may be defined as first gate spacers, second gate spacers, and third gate spacers 113.

For example, second semiconductor layers (“22” of FIG. 6) that remain below the first dummy gate DG1 on the active pattern 11 after the formation of the first and second trenches T41 and T42 may be defined as a first plurality of nanosheets NW1. For example, second semiconductor layers 22 that remain below the second dummy gate DG2 on the active pattern 11 after the formation of the first and second trenches T41 and T42 may be defined as a second plurality of nanosheets NW2. For example, second semiconductor layers 22 that remain below the third dummy gate DG3 on the active pattern 11 after the formation of the first and second trenches T41 and T42 may be defined as a third plurality of nanosheets NW3.

For example, the first trench T41 may extend into the active pattern 11. That is, the bottom surface of the first trench T41 may be defined by the active pattern 11. For example, the sidewalls, in the first horizontal direction DR1, of the first trench T41 may have a continuous slope profile. In other words, the sidewalls, in the first horizontal direction DR1, of the first plurality of nanosheets NW1, first semiconductor layers 21, and the active pattern 11, exposed through the first trench T41, may be aligned. Additionally, the sidewalls, in the first horizontal direction DR1, of the second plurality of nanosheets NW2, the first semiconductor layers 21, and the active pattern 11, exposed through the first trench T41, may also be aligned.

For example, the second trench T42 may extend into the active pattern 11. That is, the bottom surface of the second trench T42 may be defined by the active pattern 11. For example, the sidewalls, in the first horizontal direction DR1, of the second trench T42 may have a continuous slope profile. In other words, the sidewalls, in the first horizontal direction DR1, of the second plurality of nanosheets NW2, the first semiconductor layers 21, and the active pattern 11, exposed through the second trench T42, may be aligned. Additionally, the sidewalls, in the first horizontal direction DR1, of the third plurality of nanosheets NW3, the first semiconductor layers 21, and the active pattern 11, exposed through the second trench T42, may also be aligned.

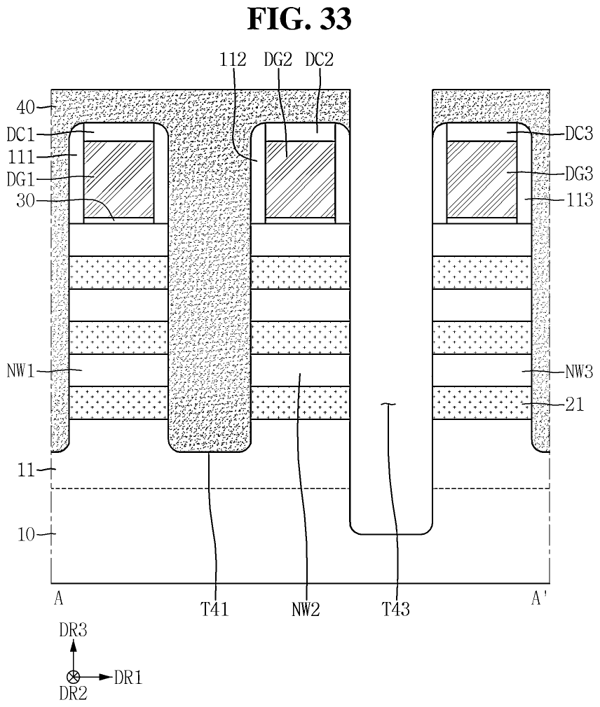

Referring to FIG. 33, a protective layer 40 may be formed in an entire region except for the second trench T42. That is, the protective layer 40 may expose only the second trench T42. For example, the protective layer 40 may include a spin-on-hardmask (SOH).

Thereafter, a third trench T43 may be formed by etching parts of the active pattern 11 and the substrate 10 through the second trench T42. For example, the third trench T43 may extend into the substrate 10. That is, the bottom surface of the third trench T43 may be defined by the substrate 10. For example, the sidewalls, in the first horizontal direction DR1, of the third trench T43 may have a continuous slope profile. In other words, the sidewalls, in the first horizontal direction DR1, of the second plurality of nanosheets NW2, the first semiconductor layers 21, the active pattern 11, and the substrate 10, exposed through the third trench T43, may be aligned. Additionally, the sidewalls, in the first horizontal direction DR1, of the third plurality of nanosheets NW3, the first semiconductor layers 21, the active pattern 11, and the substrate 10, exposed through the third trench T43, may also be aligned.

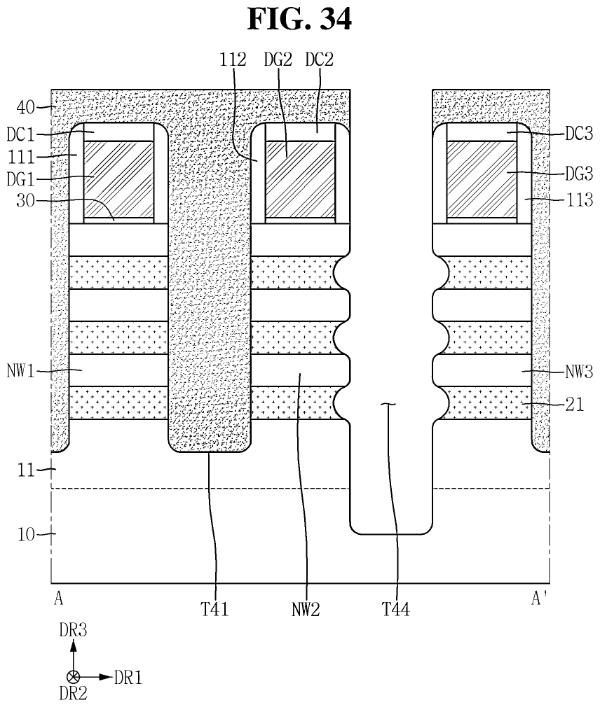

Referring to FIG. 34, parts of the sidewalls, in the first horizontal direction DR1, of the first semiconductor layers 21, exposed through the third trench T43, may be partially etched. For example, parts of the sidewalls, in the first horizontal direction DR1, of the first semiconductor layers 21, exposed through the third trench T43, between the active pattern 11 and the lowermost nanosheet of the second plurality of nanosheet NW2, may be etched. Additionally, parts of the sidewalls, in the first horizontal direction DR1, of the first semiconductor layers 21, exposed through the third trench T43, between the second plurality of nanosheets NW2 that are adjacent to one another, may be etched. For example, parts of the sidewalls, in the first horizontal direction DR1, of the first semiconductor layers 21, exposed through the third trench T43, between the active pattern 11 and the lowermost nanosheet of the third plurality of nanosheet NW3, may be etched. Moreover, parts of the sidewalls, in the first horizontal direction DR1, of the first semiconductor layers 21, exposed through the third trench T43, between the third plurality of nanosheets NW3 that are adjacent to one another, may be etched. For example, a region including the third trench T43 and the part from which the sidewalls of the first semiconductor layers 21 have been partially etched and the third trench T43 may be defined as a fourth trench T44.

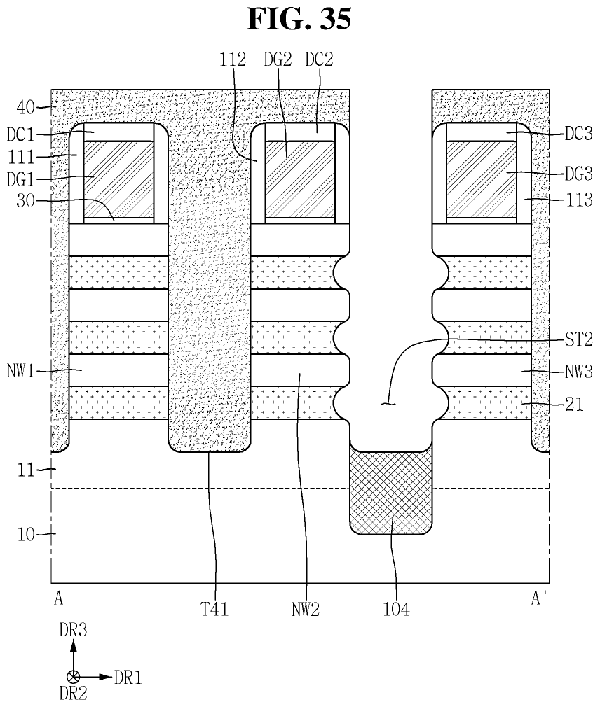

Referring to FIG. 35, a second sacrificial pattern 104 may be formed inside the fourth trench T44. The second sacrificial pattern 104 may fill part of the fourth trench T44. For example, part of the fourth trench T44 that remains unfilled on the top surface of the second sacrificial pattern 104 may be defined as a second source/drain trench ST2. For example, the second sacrificial pattern 104 may be formed by epitaxial growth.

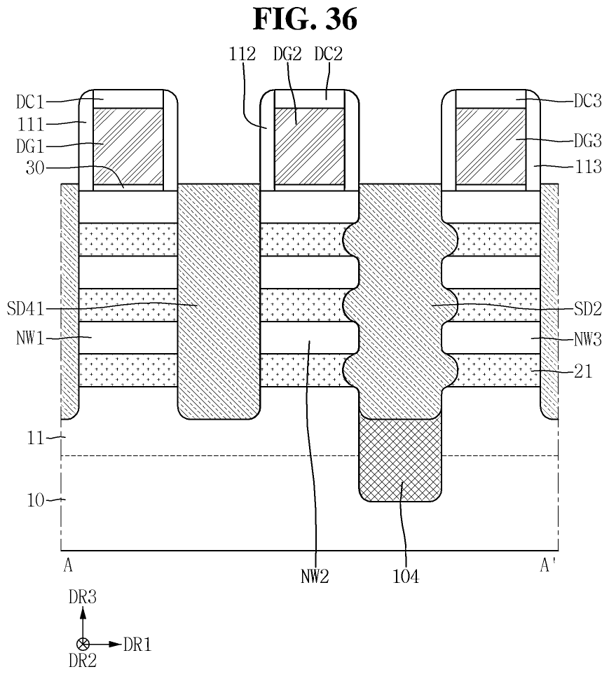

Referring to FIG. 36, the protective layer 40 may be removed. Thereafter, a first source/drain region SD41 may be formed inside the first trench T41. Also, a second source/drain region SD2 may be formed inside the second source/drain trench ST2. Thereafter, the processes depicted in FIGS. 12 through 24 may be performed.

Referring back to FIG. 31, a bottom source/drain contact BCA may be formed inside a contact trench (“CT” of FIG. 24). Additionally, a bottom silicide layer BSL may be formed between the bottom source/drain contact BCA and the second source/drain region SD2. In this manner, the semiconductor device of FIG. 31 may be obtained.

While embodiments have been described with reference to the attached drawings in accordance with the technical spirit of the present disclosure, it should be understood that the present disclosure is not limited to these embodiments. The present disclosure may be fabricated in various different forms, and those of ordinary skill in the art will appreciate that the embodiments may be carried out in other specific forms without changing the technical spirit or essential features of the present disclosure. Therefore, the embodiments described above should be considered in all respects as illustrative and not restrictive.

What is claimed is:

1. A method of fabricating a semiconductor device, comprising:
forming an active pattern extending in a first horizontal direction on a substrate;
forming a stacked structure on the active pattern, the stacked structure including alternating first semiconductor layers and second semiconductor layers;
forming a dummy gate on the stacked structure such that the dummy gate extends in a second horizontal direction different from the first horizontal direction;
etching the stacked structure such that a first trench is formed on a first side of the dummy gate and a second trench extending into the substrate is formed on a second side of the dummy gate opposite to the first side of the dummy gate in the first horizontal direction, and such that a plurality of nanosheets are formed from portions of the second semiconductor layers that remain after the first and second trenches are formed;
converting the first trench to a third trench and the second trench to a fourth trench by partially etching sidewalls of the first semiconductor layers exposed through the first and second trenches;
forming a first sacrificial pattern inside the fourth trench, wherein a top surface of the first sacrificial pattern is formed lower than a top surface of the active pattern;
forming a first source/drain region inside the third trench, and a second source/drain region on the top surface of the first sacrificial pattern inside the fourth trench;
forming a contact trench exposing a bottom surface of the second source/drain region by removing at least a portion of the first sacrificial pattern; and
forming a bottom source/drain contact inside the contact trench.

2. The method of claim 1, further comprising:
forming an upper interlayer insulating layer covering each of the first and second source/drain regions;
removing the dummy gate and the first semiconductor layers;
forming a gate insulating layer on a surface exposed by the removing the dummy gate and the first semiconductor layers; and
forming a gate electrode on the gate insulating layer such that the gate electrode surrounds the plurality of nanosheets.

3. The method of claim 2, wherein the gate insulating layer is in contact with each of the first and second source/drain regions.

4. The method of claim 2, further comprising, after the forming the gate electrode:
forming an upper source/drain contact extending into the first source/drain region by penetrating the upper interlayer insulating layer in a vertical direction.

5. The method of claim 1, wherein at least part of the second source/drain region is formed between nanosheets of the plurality of nanosheets adjacent to each other in the vertical direction.

6. The method of claim 1, wherein the first trench extends into the substrate.

7. The method of claim 6, further comprising:
forming a second sacrificial pattern inside the third trench.

8. The method of claim 1, wherein the partially etching the sidewalls of the first semiconductor layers comprises:
etching a part of the sidewalls in the first horizontal direction of the first semiconductor layers exposed through the first trench, and etching another part of the sidewalls in the first horizontal direction of the first semiconductor layers exposed through the second trench.

9. The method of claim 1, wherein the partially etching the sidewalls of the first semiconductor layers comprises:
etching a part of the sidewalls in the first horizontal direction of the first semiconductor layers exposed through the second trench without etching another part of the sidewalls in the first horizontal direction of the first semiconductor layers exposed through the first trench.

10. The method of claim 1, further comprising, before the forming the contact trench:
removing the substrate and the active pattern,
forming an insulating pattern extending in the first horizontal direction in an area from which the active pattern is removed, and
forming a lower interlayer insulating layer in an area from which the substrate is removed.

11. The method of claim 1, further comprising, after the forming the bottom source/drain contact:
removing the substrate and the active pattern,
forming an insulating pattern extending in the first horizontal direction in an area from which the active pattern is removed, and
forming a lower interlayer insulating layer in an area from which the substrate is removed.

12. A method of fabricating a semiconductor device, comprising:
forming an active pattern extending in a first horizontal direction on a substrate;
forming a stacked structure on the active pattern such that the stack structure includes alternating first semiconductor layers and second semiconductor layers;
forming a dummy gate on the stacked structure such that the dummy gate extends in a second direction different from the first horizontal direction;
etching the stacked structure such that a first trench extending into the substrate is formed on a first side of the dummy gate and a second trench extending into the substrate is formed on a second side of the dummy gate opposite to the first side of the dummy gate in the first horizontal direction and such that a plurality of nanosheets are formed from portions of the second semiconductor layers that remain after the first and second trenches are formed;
converting the first trench to a third trench and the second trench to a fourth trench by partially etching sidewalls the first semiconductor layers exposed through the first trench, and by partially etching the sidewalls of the first semiconductor layers exposed through the second trench;
forming a first sacrificial pattern inside the third trench, and a second sacrificial pattern in the fourth trench such that top surfaces of the first and second sacrificial patterns are lower than a top surface of the active pattern;
forming a first source/drain region on the top surface of the first sacrificial pattern inside the third trench and a second source/drain region on the top surface of the second sacrificial pattern inside the fourth trench;
forming an upper interlayer insulating layer such that the upper interlayer insulating layer covers each of the first and second source/drain regions;
removing the dummy gate and the first semiconductor layers;
forming a gate insulating layer on a surface exposed by the removing the dummy gate and the first semiconductor layers;
forming a gate electrode on the gate insulating layer such that the gate electrode surrounds the plurality of nanosheets;
forming an upper source/drain contact extending to the first source/drain region by penetrating the upper interlayer insulating layer in a vertical direction;
forming a contact trench exposing a bottom surface of the second source/drain region by removing the second sacrificial pattern; and
forming a bottom source/drain contact inside the contact trench,
wherein at least part of the first source/drain region and at least part of the second source/drain region are formed between nanosheets, of the plurality of nanosheets, adjacent to each other in the vertical direction, and
wherein the gate insulating layer is in contact with each of the first and second source/drain regions.

13. The method of claim 12, further comprising, before the forming the contact trench:
removing the substrate and the active pattern; and
forming an insulating pattern extending in the first horizontal direction in an area from which the active pattern is been removed, and forming a lower interlayer insulating layer in an area from which the substrate is removed.

14. A semiconductor device comprising:
a lower interlayer insulating layer;
an insulating pattern extending in a first horizontal direction on the lower interlayer insulating layer;
a plurality of nanosheets stacked on the insulating pattern spaced apart from one another in a vertical direction;
a gate electrode extending in a second horizontal direction different from the first horizontal direction on the insulating pattern, the gate electrode surrounding the plurality of nanosheets;
a first source/drain region on a first side of the gate electrode such that the first source/drain region contacts first sidewalls of the plurality of nanosheets;
a second source/drain region on a second side of the gate electrode opposite to the first side of the gate electrode in the first horizontal direction such that the second source/drain region contacts second sidewalls of the plurality of nanosheets opposite to the first sidewalls of the plurality of nanosheets; and
a bottom source/drain contact penetrating the lower interlayer insulating layer and the insulating pattern in the vertical direction such that the bottom source/drain contact is electrically connected to the second source/drain region,
wherein at least part of the second source/drain region is disposed between nanosheets, of the plurality of nanosheets, adjacent to each other in the vertical direction.

15. The semiconductor device of claim 14, further comprising:
an upper interlayer insulating layer covering each of the first and second source/drain regions; and
an upper source/drain contact penetrating the upper interlayer insulating layer in the vertical direction such that the upper source/drain contact is contact electrically connected to the first source/drain region.

16. The semiconductor device of claim 14, further comprising:
a gate insulating layer between the gate electrode and each of the first and second source/drain regions such that the gate insulating layer contacts each of the first and second source/drain regions.

17. The semiconductor device of claim 14, wherein at least part of the first source/drain region is disposed between the nanosheets adjacent to each other in the vertical direction.

18. The semiconductor device of claim 14, further comprising:
a sacrificial pattern below the first source/drain region in the lower interlayer insulating layer and the insulating pattern.

19. The semiconductor device of claim 14, wherein a bottom surface of the first source/drain region is entirely in contact with the insulating pattern.

20. The semiconductor device of claim 14, wherein the first source/drain region is not disposed between adjacent the plurality of nanosheets.
